(19) United States
(12) Patent Application Publication
(10) Pub. No.: US 2024/0081087 A1
(43) Pub. Date: Mar. 7, 2024

(54) LIGHT-EMITTING DEVICE, METHOD OF MANUFACTURING THE LIGHT-EMITTING DEVICE, AND METHOD OF OPERATING THE LIGHT-EMITTING DEVICE

(71) Applicants: Samsung Electronics Co., Ltd., Suwon-si (KR); Korea Advanced Institute of Science and Technology, Daejeon (KR)

(72) Inventors: Joonghyuk KIM, Suwon-si (KR); Muhyun Baik, Daejeon (KR); Eunji Lee, Daejeon (KR); Seungyeon Kwak, Suwon-si (KR); Yongsik Jung, Suwon-si (KR); Hyejin Moon, Daejeon (KR); Kyuyoung Hwang, Suwon-si (KR); Yerin Park, Daejeon (KR); Changjin Oh, Daejeon (KR); Joonghee Won, Suwon-si (KR); Hyeonho Choi, Suwon-si (KR)

(21) Appl. No.: 18/447,070

(22) Filed: Aug. 9, 2023

(30) Foreign Application Priority Data
Aug. 9, 2022 (KR) 10-2022-0099435

(51) Int. Cl. H10K 50/115; H10K 85/30; H10K 85/60

(52) U.S. Cl. CPC H10K 50/115; H10K 85/342; H10K 85/346; H10K 85/615; H10K 85/631; H10K 85/654; H10K 85/656; H10K 85/6574; H10K 85/6576; H10K 85/658; H10K 2102/20

(57) ABSTRACT

A light-emitting device, a method of manufacturing the light-emitting device, and a method of operating the light-emitting device. The light-emitting device includes a first conductive layer comprising gold, an interlayer disposed on a surface of the first conductive layer, the interlayer comprises an inorganic salt, and a plurality of light-emitting group represented by Formula 1 chemically bonded to the surface of the first conductive layer.

Formula 1

*—A₃—(A₁)ₘ₁—(A₂)ₘ₂

A detailed description of Formula 1 is the same as described in this specification.

### CROSS-REFERENCE TO RELATED APPLICATION

This application claims priority to Korean Patent Application No. 10-2022-0099435, filed on Aug. 9, 2022, in the Korean Intellectual Property Office, and all the benefits accruing therefrom under 35 U.S.C. § 119, the disclosure of which is herein incorporated by reference in its entirety.

### BACKGROUND

### 1. Field

The disclosure relates to a light-emitting device, a method of manufacturing the light-emitting device, and a method of operating the light-emitting device.

### 2. Description of the Related Art

The research and development on various light-emitting devices that can be used in devices such as various displays and light sources is of interest and ongoing. Organic light-emitting devices are self-emissive devices that can produce full-color images and have excellent optical and/or electronic characteristics such as viewing angles, response time, luminance, driving voltage, and response speed.

For example, an organic light-emitting device includes an anode, a cathode, and an organic layer arranged between the anode and the cathode, wherein the organic layer includes an emission layer. A hole transport region may be arranged between the anode and the emission layer, and an electron transport region may be arranged between the emission layer and the cathode. Holes provided from the anode move toward the emission layer through the hole transport region, and electrons provided from the cathode move toward the emission layer through the electron transport region. The holes and the electrons recombine in the emission layer to produce excitons. These excitons then transition from an excited state to the ground state to emit light, e.g., with an emission peak in the visible region of the spectrum.

There remains a need to not only further develop such organic light-emitting devices, but also, to develop next-generation light-emitting devices.

### SUMMARY

Provided are a light-emitting device, a method of manufacturing the light-emitting device, and a method of operating the light-emitting device.

Additional aspects will be set forth in part in the description which follows and, in part, will be apparent from the description, or may be learned by practice of the presented embodiments of the disclosure.

According to an aspect of the disclosure, a light-emitting device includes
a first conductive layer comprising gold,
an interlayer disposed on a surface of the first conductive layer, wherein the interlayer comprises an inorganic salt; and
a plurality of light-emitting groups represented by Formula 1 chemically bonded to the surface of the first conductive layer,

### Formula 1

*—A₃—(A₁)ₘ₁—(A₂)m₂.

### in Formula 1,

may indicate a chemical binding site of the light emitting groups to gold at the surface of the first conductive layer,
A₃ may be an atom bonded to the gold at the surface of the first conductive layer,
A₁ may be a linking group,
A₂ may be a luminescent moiety, and
m1 and m2 may each independently be an integer from 1 to 10, wherein, when m1 is 2 or more, two or more A₁ may be the same or different from each other, and when m2 is 2 or more, two or more A₂ may be the same or different from each other.

According to another aspect of the disclosure, a method of manufacturing a light-emitting device includes
providing a first conductive layer comprising gold, e.g., a gold layer,
chemically bonding a light-emitting group represented by Formula 1 to a surface of the first conductive layer by bringing the first conductive layer into contact with a compound represented by Formula 1A, and
providing an interlayer on one surface of the first conductive layer, wherein the interlayer includes an inorganic salt,

### Formula 1A

A₄—A₃—(A₁)ₘ₁—(A₂)m₂

### Formula 1

*—A₃—(A₁)ₘ₁—(A₂)m₂.
A₄ in Formulae 1A may be a moiety that is displaced upon A₃ bonding to the surface, and in Formulae 1A and 1, *, A₃, A₁, A₂, m1, and m2 are the same as described above.

According to another aspect of the disclosure, a method of operating a light-emitting device includes controlling a voltage applied across the first conductive layer and the second conductive layer of the light-emitting device.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic cross-sectional view of a light-emitting device according to an embodiment;

FIG. 2 is a schematic view of a first conductive layer with a plurality of light-emitting groups of the light-emitting device of FIG. 1; and

FIG. 3 is a plot showing a photoluminescence (PL) spectrum with respect to a voltage applied to a light-emitting device 1 of Example 1.

### DETAILED DESCRIPTION

Reference will now be made in detail to embodiments, examples of which are illustrated in the accompanying drawings, wherein like reference numerals refer to like elements throughout the specification. In this regard, the present embodiments may have different forms and should not be construed as being limited to the descriptions set forth herein.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10% or ±5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

As used herein, when a definition is not otherwise provided, “substituted” refers to replacement of hydrogen of a compound, a group, or a moiety by a C1 to C30 alkyl group, a C2 to C30 alkenyl group, a C2 to C30 alkynyl group, a C2 to C30 epoxy group, a C2 to C30 alkyl ester group (—C(═O)OR, wherein R is a C1 to C29 alkyl group), a C7 to C13 aryl ester group (—C(═O)OR, wherein R is a C6 to C12 aryl group), a C3 to C30 alkenyl ester group (—C(═O)OR, wherein R is a C2 to C29 alkenyl group, e.g., an alkenyl ester group such as an acrylate group, a methacrylate group, or the like), a C6 to C30 aryl group, a C7 to C30 alkylaryl group, a C1 to C30 alkoxy group, a C1 to C30 heteroalkyl group, a C3 to C30 heteroalkylaryl group, a C3 to C30 cycloalkyl group, a C3 to C15 cycloalkenyl group, a C3 to C30 cycloalkynyl group, a C2 to C30 heterocycloalkyl group, a halogen (—F, —Cl, —Br, or —I), a hydroxy group (—OH), a nitro group (—NO₂), a cyano group (—CN), an amino or amine group (—NRR′ wherein R and R′ are each independently hydrogen or a C1 to C6 alkyl group), an azido group (—N₃), an amidino group (—C(═NH)NH₂), a hydrazino group (—NHNH₂), a hydrazono group (═N(NH₂)), an aldehyde group (—C(═O)H), a carbamoyl group (—C(O)NH₂), a thiol group (—SH), a carboxyl group (—COOH) or a salt thereof (—C(═O)OM, wherein M is an organic or inorganic cation), a sulfonic acid group (—SO₃H) or a salt thereof (—SO₃M, wherein M is an organic or inorganic cation), a phosphoric acid group (—PO₃H₂) or a salt thereof (—PO₃MH or —PO₃M₂, wherein M is an organic or inorganic cation), or a combination thereof.

As used herein, “alkylene group” refers to a straight or branched saturated hydrocarbon group having at least two valences and optionally substituted with a substituent. Examples of a divalent alkylene group having 2 to 16 carbon atoms may include methylene, ethylene, propylene, or butylene. As used herein, “alkenylene group” refers to a straight or branched unsaturated hydrocarbon with at least one carbon-carbon double bond having at least two valences and optionally substituted with a substituent. Examples of a divalent alkenyl group having 2 to 16 carbon atoms may include a vinyl group, an allyl group, a 1-propenyl group, a 2-butenyl group, a 1,3-butadienyl group, a 2-pentenyl group, an isopropenyl group, and the like. As used herein, “alkynylene group” refers to a straight or branched unsaturated hydrocarbon with at least one carbon-carbon triple bond having at least two valences and optionally substituted with a substituent. Examples of a divalent alkynyl group having 2 to 16 carbon atoms may include an ethynyl group or a propargyl group.

As used herein, “arylene group” refers to a bivalent or polyvalent aromatic group (i.e., a group derived from an arene) that is obtained by removal of a hydrogen atom from at least two ring carbon atoms of the aromatic ring(s), and optionally may be substituted with a substituent.

As used herein, when a definition is not otherwise provided, “alkyl” refers to a linear or branched saturated monovalent hydrocarbon group (methyl, ethyl hexyl, etc.). Unless specified otherwise, an alkyl group has from 1 to 60 carbon atoms, or 1 to 18 carbon atoms, or 1 to 12 carbon atoms.

As used herein, when a definition is not otherwise provided, “alkenyl” refers to a linear or branched monovalent hydrocarbon group having one or more carbon-carbon double bond. In an embodiment, an alkenyl group may have from 2 to 60 carbon atoms, or 2 to 18 carbon atoms, or 2 to 12 carbon atoms.

As used herein, when a definition is not otherwise provided, “alkynyl” refers to a linear or branched monovalent hydrocarbon group having one or more carbon-carbon triple bond. In an embodiment, an alkenyl group may have from 2 to 60 carbon atoms, or 2 to 18 carbon atoms, or 2 to 12 carbon atoms.

As used herein, “carbocyclic group” refers to a non-aromatic ring (alicyclic) of carbon-ring atoms, and includes a monovalent C3 to C30 cycloalkyl group or a C3 to C30 cycloalkenyl group, or a divalent C3 to C30 cycloalkylene group or a C3 to C30 cycloalkenylene group. The term “carbocyclic group” also refers to an aromatic ring and includes a monovalent or bivalent C6 to C30 group including one aromatic ring, two or more aromatic rings fused together to provide a condensed ring system, or two or more moieties independently of the foregoing (a single aromatic ring or a condensed ring system) linked through a single bond or through a functional group such as a fluorenylene group, —O—, —S—, —C(═O)—, —CH(OH)—, —S(═O)₂—, —Si(CH₃)₂—, —(CH₂)p— wherein 1≤p≤10, —(CF₂)q— wherein 1≤q≤10, —C(CH₃)₂—, —C(CF₃)₂—, or —C(═O)NH—, for example, through —S(═O)₂—, for example a C6 to C30 aryl group or a C6 to C30 arylene group, for example, a C6 to C16 aryl group or a C6 to C16 arylene group such as phenylene.

As used herein, the term “heterocyclic group” refers to a C2 to C30 heterocycloalkyl group, a C2 to C30 heterocycloalkylene group, a C2 to C30 heterocycloalkenyl group, a C2 to C30 heterocycloalkenylene group, a C2 to C30 heteroaryl group, or a C2 to C30 heteroarylene group, each including 1 to 3 heteroatoms such as O, S, N, P, Si, or a combination thereof in one ring, for example, a C2 to C15 heterocycloalkyl group, a C2 to C15 heterocycloalkylene group, a C2 to C15 heterocycloalkenyl group, a C2 to C15 heterocycloalkenylene group, a C2 to C15 heteroaryl group, or a C2 to C15 heteroarylene group, each including 1 to 3 heteroatoms such as O, S, N, P, Si, or a combination thereof, in at least one ring.

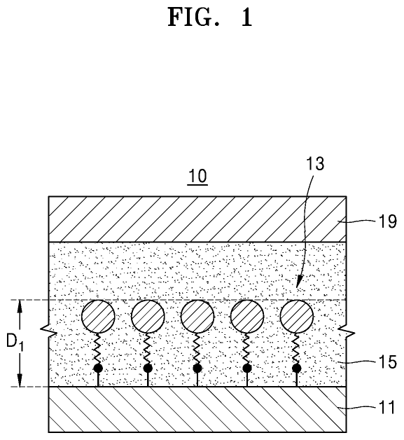

FIG. 1 is a schematic cross-sectional view of a light-emitting device 10 according to an embodiment.

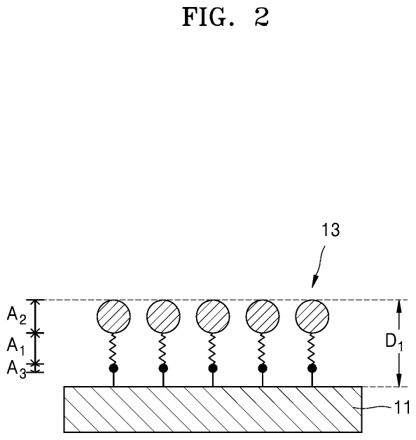

FIG. 2 is a schematic view of a first conductive layer 11 and a plurality of light-emitting groups 13 of the light-emitting device 10 of FIG. 1.

The light-emitting device 10 of FIG. 1 includes a first conductive layer 11, the light-emitting groups 13, a second conductive layer 19 facing the first conductive layer 11, and an interlayer 15 disposed between the first conductive layer 11 and the second conductive layer 19. The first conductive layer 11 includes gold (Au), e.g., a (Au)-containing layer.

In an embodiment, the first conductive layer 11 may include a metal, a metalloid, carbon, nitrogen, oxygen, or any combination thereof, in addition to the gold.

For example, the first conductive layer 11 may include magnesium (Mg), calcium (Ca), scandium (Sc), yttrium (Y), lanthanum (La), actinium (Ac), titanium (Ti), zirconium (Zr), hafnium (Hf), cerium (Ce), vanadium (V), niobium (Nb), tantalum (Ta), chromium (Cr), molybdenum (Mo), tungsten (W), neodymium (Nd), manganese (Mn), rhenium (Re), iron (Fe), cobalt (Co), nickel(Ni), copper (Cu), silver (Ag), zinc (Zn), aluminum (Al), gallium (Ga), indium (In), thallium (Tl), tin (Sn), bismuth (Bi), boron (B), silicon (Si), germanium (Ge), arsenic (As), antimony (Sb), tellurium (Te), carbon, nitrogen, oxygen, or any combination thereof, in addition to the gold (Au).

For example, the first conductive layer 11 may further include Ag, Zn, Al, Ga, In, Tl, Sn, or any combination thereof. In an embodiment, the first conductive layer 11 may be a Au layer, i.e., at least 95 weight percent gold, but the disclosure is not limited thereto.

In an embodiment, the first conductive layer 11 may further include Ag, Zn, Al, Ga, In, Tl, Sn, or any combination thereof; and oxygen, in addition to Au. In an embodiment, the first conductive layer 11 may be an ITO layer in which an Au layer is stacked on a surface of the ITO layer, but the disclosure is not limited thereto.

A thickness of the first conductive layer 11 may be, for example, about 0.1 nanometers (nm) to about 5 nm.

The light-emitting group 13 is chemically bonded at the surface of the first conductive layer 11, e.g., an atom (in particular, an atom of gold) at the surface of the first conductive layer 11. This structure is clearly distinguished from a structure in which luminescent compound molecules are randomly and physically oriented or positioned on an electrode through a deposition method (for example, a vacuum deposition method) and/or a coating method (for example, a spin coating method and a laser printing method).

A monolayer including a plurality of light-emitting groups 13 is located on a surface of the first conductive layer 11, and the monolayer including the plurality of light-emitting groups 13 may be in direct contact with the surface of the first conductive layer 11. This structure could be identified from the feature wherein the light-emitting group 13 is represented by Formula 1 below and * in Formula 1 is a chemical binding site to gold, e.g., an atom of gold, at the surface of the first conductive layer 11.

A thickness (D₁) of the monolayer including the plurality of light-emitting groups 13 may vary depending on the length of the light-emitting groups 13, and may be, for example, about 0.1 nm to about 5.0 nm, or about 0.5 nm to about 2.0 nm.

The monolayer including the plurality of light-emitting groups 13 may further include any groups different than the light-emitting groups 13. For example, the monolayer including the plurality of light-emitting groups 13 may also include a A₂-free group among groups as represented by Formula 1. From among groups represented by Formula 1, the A₂-free group may be formed when the bond between A₁ and A₂ is broken, or A₁ and A₂ are not bonded to each other.

The monolayer including the plurality of light-emitting groups 13 may be a self-assembled monolayer. Accordingly, a self-assembled monolayer including the plurality of light-emitting groups 13 may be disposed on and in direct contact with the first conductive layer 11.

The light-emitting group 13 may be represented by Formula 1:

### Formula 1

*—A₃—(A₁)ₘ₁—(A₂)ₘ₂
wherein, * in Formula 1 may indicate a chemical binding site to gold, e.g., an atom of gold, at the surface of the first conductive layer 11.

In an embodiment, the atom on the surface of the first conductive layer 11 to which light-emitting group 13 is chemically bound may include Au, or may include an atom of Mg, Ca, Sc, Y, La, Ac, Ti, Zr, Hf, Ce, V, Nb, Ta, Cr, Mo, W, Nd, Mn, Re, Fe, Co, Ni, Cu, Ag, Zn, Al, Ga, In, Tl, Sn, Bi, or any combination thereof, in addition to Au.

In an embodiment, the first conductive layer 11 may further include Ag, Zn, Al, Ga, In, TI, Sn, or any combination thereof, in addition to Au, and * in Formula 1 may be a chemical binding site to an atom of Au and/or, Ag, Zn, Al, Ga, In, Tl, or Sn, at the surface of the first conductive layer 11.

In an embodiment, the atom on the surface of the first conductive layer 11 may include metalloid, in addition to Au, and the metalloid may be B, Si, Ge, As, Sb, Te, or a combination thereof.

Accordingly, A₃ in Formula 1, is an atom that connects the light-emitting group 13 to the surface of the first conductive layer 11 and may be an atom that is bonded to the atom on the surface of the first conductive layer 11. A3 may be, for example, O or S.

A₁ in Formula 1 is a linking group and may connect A₃ to A₂ in Formula 1 and may provide a degree of rigidity to the light-emitting group 13. For example, A₁ may transfer charges to A₂, that is, the luminescent moiety when a voltage is applied across the first conductive layer 11 and/or the second conductive layer 19.

For example, A₁ in Formula 1 may be a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₅-C₃₀ carbocyclic group, or a substituted or unsubstituted C₂-C₃₀ heterocyclic group.

In an embodiment, A₁ in Formula 1 may be a single bond, a C₂-C₆₀ alkenylene group that is unsubstituted or substituted with at least one R₁₀ₐ, a C₂-C₆₀alkynylene group that is unsubstituted or substituted with at least one R₁₀ₐ, a C₅-C₃₀ carbocyclic group that is unsubstituted or substituted with at least one R₁₀ₐ, or a C₂-C₃₀ heterocyclic group that is unsubstituted or substituted with at least one R₁₀ₐ, wherein R₁₀ₐ is the same as described in connection with R₁₀ (see below).

In an embodiment, A₁ in Formula 1 may be:
a single bond; a C₂-C₂₀ alkenylene group, a C₂-C₂₀alkynylene group, a cyclopentane group, a cyclohexane group, a cycloheptane group, a cyclopentene group, a cyclohexene group, a cycloheptene group, an adamantane group, norbornane group, a norbornene group, a bicyclo[1.1.1]pentane group, a bicyclo[2.1.1]hexane group, a bicyclo[2.2.2]octane group, a benzene group, a naphthalene group, an anthracene group, a phenanthrene group, a triphenylene group, a pyrene group, a chrysene group, a 1,2,3,4-tetrahydronaphthalene group, a pyrrole group, a borole group, a phosphole group, a cyclopentadiene group, a silole group, a germole group, a thiophene group, a selenophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a benzoquinoline group, a benzoisoquinoline group, a quinoxaline group, a quinazoline group, a phenanthroline group, a pyrazole group, an imidazole group, a triazole group, an azaborole group, an azaphosphole group, an azacyclopentadiene group, an azasilole group, an azagermole group, an azaselenophene group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, or a 5,6,7,8-tetrahydroquinoline group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀) alkyl group, a deuterated C₂-C₂₀ alkyl group, a C₁-C₂₀ alkoxy group, a cyclopentyl group, a cyclohexyl group, a cycloheptyl group, a cyclooctyl group, an adamantanyl group, a norbornanyl group (or, a bicyclo[2.2.1]heptyl group), a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof.

In an embodiment, an energy level (eV) of the highest occupied molecular orbital (HOMO) of a conjugate represented by *-A₃-(A₁)ₘ₁-*′ may be about −5.5 eV to about −6.5 eV. The HOMO energy level may be calculated according to B3LYP density functional theory (DFT), wherein *′ indicates a chemical binding site to A₂.

A₂ in Formula 1 may be a luminescent moiety and may be a monovalent group derived from a phosphorescent luminescent compound, a fluorescent luminescent compound, or a quantum dot.

A₂ in Formula 1 may be induced to have a maximum change in intensity of light emitted from the light-emitting group 13 when a voltage is applied across the first conductive layer 11 and the second conductive layer 19.

The phosphorescent luminescent compound, the fluorescent luminescent compound, and the quantum dot may be any phosphorescent luminescent compound, any fluorescent luminescent compound, or any quantum dot which are arranged between a pair of electrodes of a light-emitting device, for example, an organic light-emitting device.

The term “a monovalent group derived from material X” used herein refers to a group in which a site of material X from which an arbitrary atom (for example, hydrogen) is removed, becomes a binding site to a neighboring atom. For example, a monovalent group derived from methane (CH₄) refers to a methyl group (*—CH₃, wherein * indicates a binding site to any other atom).

In an embodiment, A₂ in Formula 1 may not be a phenyl group that is unsubstituted or substituted with a substituent.

In an embodiment, A₂ of Formula 1 may be a monovalent group derived from an organometallic compound capable of emitting phosphorescent light.

In an embodiment, the organometallic compound may include a transition metal. Therefore, A₂ in Formula 1 may be a monovalent group derived from a transition metal-containing organometallic compound.

In an embodiment, the organometallic compound may include iridium (Ir), platinum (Pt), osmium (Os), rhodium (Rh), ruthenium (Ru), Re, palladium (Pd), or Au. Therefore, A₂ in Formula 1 may be a monovalent group derived from an organometallic compound including Ir, Pt, Os, Rh, Ru, Re, Pd, or Au.

The organometallic compound may further include at least one ligand bonded to the transition metal, in addition to the transition metal as described above. The at least one ligand may be a ligand represented by one of Formulae 2-1 to 2-4:

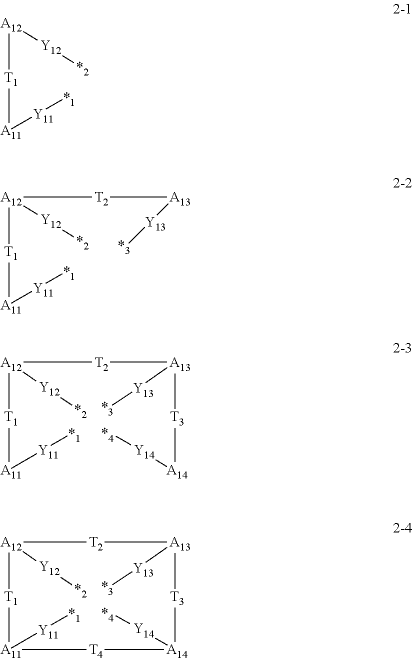

wherein, in Formulae 2-1 to 2-4,
A₁₁ to A₁₄ may each independently be a C₅-C₃₀ carbocyclic group that is unsubstituted or substituted with at least one R₁₀, a C₁-C₃₀ heterocyclic group that is unsubstituted or substituted with at least one R₁₀, or a non-cyclic group,
Y₁₁ to Y₁₄ may each independently be a chemical bond (for example, a covalent bond and a coordinate bond), O, S, N(R₉₁), B(R₉₁), P(R₉₁), or C(R₉₁)(R₉₂),
T₁ to T₄ may each independently be a single bond, a double bond, *—N(R₉₃)—*′, *—B(R₉₃)—*′, *—P(R₉₃)—*′, *—C(R₉₃)(R₉₄)—*′, *—Si(R₉₃)(R₉₄)—*′, *—Ge(R₉₃)(R₉₄)—*', *—S—*′, *—Se—*′, *—O—*′, *—C(═O)—*′, *—S(═O)—*′, *—S(═O)₂—*′, *—C(R₉₃)═*′, *═C(R₉₃)—*′, *—C(R₉₃)═C(R₉₄)—*′, *—C(═S)—*′, or *—C≡—*′,
R₁₀ and R₉₁ to R₉₄ may each independently be hydrogen, deuterium, —F, —Cl, —Br, —I, —SF₅, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a substituted or unsubstituted C₁-C₆₀ alkyl group, a substituted or unsubstituted C₂-C₆₀ alkenyl group, a substituted or unsubstituted C₂-C₆₀ alkynyl group, a substituted or unsubstituted C₁-C₆₀ alkoxy group, a substituted or unsubstituted C₃-C₁₀ cycloalkyl group, a substituted or unsubstituted C₁-C₁₀ heterocycloalkyl group, a substituted or unsubstituted C₃-C₁₀ cycloalkenyl group, a substituted or unsubstituted C₁-C₁₀ heterocycloalkenyl group, a substituted or unsubstituted C₆-C₆₀ aryl group, a substituted or unsubstituted C₆-C₆₀ aryloxy group, a substituted or unsubstituted C₆-C₆₀ arylthio group, a substituted or unsubstituted C₁-C₆₀ heteroaryl group, a substituted or unsubstituted monovalent non-aromatic condensed polycyclic group, a substituted or unsubstituted monovalent non-aromatic condensed heteropolycyclic group, —N(Q₁)(Q₂), —Si(Q₃)(Q₄)(Q₆), —Ge(Q₃)(Q₄)(Q₅), —B(Q₆)(Q₇), —P(═O)(Q₈)(Q₉), or P(Q₈)(Q₉),
*1, *2, *3, and *4 each indicate a binding site of the organometallic compound to a transition metal,
a substituent of the substituted C₁-C₆₀ alkyl group, the substituted C₂-C₆₀ alkenyl group, the substituted C₂-C₆₀ alkynyl group, the substituted C₁-C₆₀ alkoxy group, the substituted C₃-C₁₀ cycloalkyl group, the substituted C₁-C₁₀ heterocycloalkyl group, the substituted C₃-C₁₀ cycloalkenyl group, the substituted C₁-C₁₀heterocycloalkenyl group, the substituted C₆-C₆₀ aryl group, the substituted C₆-C₆₀ aryloxy group, the substituted C₆-C₆₀ arylthio group, the substituted C₁-C₆₀ heteroaryl group, the substituted monovalent non-aromatic condensed polycyclic group, and the substituted monovalent non-aromatic condensed heteropolycyclic group may be:
deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, or a C₁-C₆₀ alkoxy group;

a C₁-C₆₀ alkyl group, a C₂-C₆₀ alkenyl group, a C₂-C₆₀ alkynyl group, or a C₁-C₆₀ alkoxy group, each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₁₁)(Q₁₂), —Si(Q₁₃)(Q₁₄)(Q₁₅), —Ge(Q₁₃)(Q₁₄)(Q₁₅), —B(Q₁₆)(Q₁₇), —P(═O)(Q₈)(Q₁₉), —P(Q₁₈)(Q₁₉), or any combination thereof;
a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, or a monovalent non-aromatic condensed heteropolycyclic group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid or a salt thereof, a sulfonic acid or a salt thereof, a phosphoric acid or a salt thereof, a C₁-C₆₀ alkyl group, a C₂-C₆₀ alkenyl group, a C₂-C₆₀ alkynyl group, a C₁-C₆₀ alkoxy group, a C₃-C₁₀ cycloalkyl group, a C₁-C₁₀ heterocycloalkyl group, a C₃-C₁₀ cycloalkenyl group, a C₁-C₁₀ heterocycloalkenyl group, a C₆-C₆₀ aryl group, a C₆-C₆₀ aryloxy group, a C₆-C₆₀ arylthio group, a C₁-C₆₀ heteroaryl group, a monovalent non-aromatic condensed polycyclic group, a monovalent non-aromatic condensed heteropolycyclic group, —N(Q₂₁)(Q₂₂), —Si(Q₂₃)(Q₂₄)(Q₂₅), —Ge(Q₂₃)(Q₂₄)(Q₂₅), —B(Q₂₆)(Q₂₇), —P(═O)(Q₂₈)(Q₂₉), P(Q₂₈)(Q₂₉), or any combination thereof;
—N(Q₃₁)(Q₃₂), —Ge(Q₃₃)(Q₃₄)(Q₃₅), —B(Q₃₆)(Q₃₇), —P(═O)(Q₃₈)(Q₃₉), or —P(Q₃₈)(Q₃₉), or any combination thereof, and

Q₁ to Q₉, Q₁₁ to Q₁₉, Q₂₁ to Q₂₉, and Q₃₁ to Q₃₉ may each independently be: hydrogen; deuterium; —F; —Cl; —Br; —I; a hydroxyl group; a cyano group; a nitro group; an amidino group; a hydrazine group; a hydrazone group; a carboxylic acid or a salt thereof; a sulfonic acid or a salt thereof; a phosphoric acid or a salt thereof; a C₁-C₆₀ alkyl group that is unsubstituted or substituted with deuterium, a C₁-C₆₀ alkyl group, a C₆-C₆₀ aryl group, or any combination thereof; a C₂-C₆₀ alkenyl group; a C₂-C₆₀ alkynyl group; a C₁-C₆₀ alkoxy group; a C₃-C₁₀ cycloalkyl group; a C₁-C₁₀ heterocycloalkyl group; a C₃-C₁₀ cycloalkenyl group; a C₁-C₁₀ heterocycloalkenyl group; a C₆-C₆₀ aryl group that is unsubstituted or substituted with deuterium, a C₁-C₆₀ alkyl group, a C₆-C₆₀ aryl group, or any combination thereof; a C₆-C₆₀ aryloxy group; a C₆-C₆₀ arylthio group; a C₁-C₆₀ heteroaryl group; a monovalent non-aromatic condensed polycyclic group; or a monovalent non-aromatic condensed heteropolycyclic group.

In an embodiment, in Formulae 2-1 to 2-4, A₁₁ to A₁₄ may each independently be:
a cyclopentene group, a cyclohexane group, a cyclohexene group, a benzene group, a naphthalene group, an anthracene group, a phenanthrene group, a triphenylene group, a pyrene group, a chrysene group, a cyclopentadiene group, a 1,2,3,4-tetrahydronaphthalene group, a thiophene group, a furan group, an indole group, a benzoborole group, a benzophosphole group, an indene group, a benzosilole group, a benzogermole group, a benzothiophene group, a benzoselenophene group, a benzofuran group, a carbazole group, a dibenzoborole group, a dibenzophosphole group, a fluorene group, a dibenzosilole group, a dibenzogermole group, a dibenzothiophene group, a dibenzoselenophene group, a dibenzofuran group, a dibenzothiophene 5-oxide group, a 9H-fluorene-9-one group, a dibenzothiophene 5,5-dioxide group, an azaindole group, an azabenzoborole group, an azabenzophosphole group, an azaindene group, an azabenzosilole group, an azabenzogermole group, an azabenzothiophene group, an azabenzoselenophene group, an azabenzofuran group, an azacarbazole group, an azadibenzoborole group, an azadibenzophosphole group, an azafluorene group, an azadibenzosilole group, an azadibenzogermole group, an azadibenzothiophene group, an azadibenzoselenophene group, an azadibenzofuran group, an azadibenzothiophene 5-oxide group, an aza-9H-fluorene-9-one group, an azadibenzothiophene 5,5-dioxide group, a pyridine group, a pyrimidine group, a pyrazine group, a pyridazine group, a triazine group, a quinoline group, an isoquinoline group, a quinoxaline group, a quinazoline group, a phenanthroline group, a pyrrole group, a pyrazole group, an imidazole group, a triazole group, an oxazole group, an isoxazole group, a thiazole group, an isothiazole group, an oxadiazole group, a thiadiazole group, a benzopyrazole group, a benzimidazole group, a benzoxazole group, a benzothiazole group, a benzoxadiazole group, a benzothiadiazole group, a 5,6,7,8-tetrahydroisoquinoline group, a 5,6,7,8-tetrahydroquinoline group, an adamantane group, a norbornane group, or a norbornene group, each unsubstituted or substituted with at least one R₁₀; or a carbonyl group.

In an embodiment, Y₁₁ to Y₁₄ in Formulae 2-1 to 2-4 may each independently be a chemical bond (for example, a covalent bond and a coordinate bond), O, or S.

In an embodiment, T₁ to T₄ in Formulae 2-1 to 2-4 may each independently be a single bond, *—N(R₉₃)—*′, *—B(R₉₃)—*′, *—P(R₉₃)—*′, *—C(R₉₃)(R₉₄)—*′, *—Si(R₉₃)(R₉₄)—*′, *Ge(R₉₃)(R₉₄)—*′, *—S—*′, *—Se—*′, or *—O—*′.

In an embodiment, R₁₀ and R₉₁ to R₉₄ in Formulae 2-1 to 2-4 may each independently be:
hydrogen, deuterium, —F, —Cl, —Br, —I, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, —SF₅, a C₁-C₂₀ alkyl group, or a C₁-C₂₀ alkoxy group;
a C₁-C₂₀ alkyl group or a C₁-C₂₀ alkoxy group , each substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a 1,2,3,4-tetrahydronaphthyl group, a pyridinyl group, a pyrimidinyl group, or any combination thereof;
a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, or azadibenzothiophenyl group, each unsubstituted or substituted with deuterium, —F, —Cl, —Br, —I, —CD₃, —CD₂H, —CDH₂, —CF₃, —CF₂H, —CFH₂, a hydroxyl group, a cyano group, a nitro group, an amino group, an amidino group, a hydrazine group, a hydrazone group, a carboxylic acid group or a salt thereof, a sulfonic acid group or a salt thereof, a phosphoric acid group or a salt thereof, a C₁-C₂₀ alkyl group, a deuterium-containing C₁-C₂₀ alkyl group, a C₁-C₂₀ alkoxy group, a cyclopentyl group, a cyclohexyl group, a cycloheptyl group, a cyclooctyl group, an adamantanyl group, a norbornanyl group, a norbornenyl group, a cyclopentenyl group, a cyclohexenyl group, a cycloheptenyl group, a bicyclo[1.1.1]pentyl group, a bicyclo[2.1.1]hexyl group, a bicyclo[2.2.2]octyl group, a (C₁-C₂₀ alkyl)cyclopentyl group, a (C₁-C₂₀ alkyl)cyclohexyl group, a (C₁-C₂₀ alkyl)cycloheptyl group, a (C₁-C₂₀ alkyl)cyclooctyl group, a (C₁-C₂₀ alkyl)adamantanyl group, a (C₁-C₂₀ alkyl)norbornanyl group, a (C₁-C₂₀ alkyl)norbornenyl group, a (C₁-C₂₀ alkyl)cyclopentenyl group, a (C₁-C₂₀ alkyl)cyclohexenyl group, a (C₁-C₂₀ alkyl)cycloheptenyl group, a (C₁-C₂₀ alkyl)bicyclo[1.1.1]pentyl group, a (C₁-C₂₀ alkyl)bicyclo[2.1.1]hexyl group, a (C₁-C₂₀ alkyl)bicyclo[2.2.2]octyl group, a phenyl group, a (C₁-C₂₀ alkyl)phenyl group, a biphenyl group, a terphenyl group, a naphthyl group, a 1,2,3,4-tetrahydronaphthyl group, a fluorenyl group, a phenanthrenyl group, an anthracenyl group, a fluoranthenyl group, a triphenylenyl group, a pyrenyl group, a chrysenyl group, a pyrrolyl group, a thiophenyl group, a furanyl group, an imidazolyl group, a pyrazolyl group, a thiazolyl group, an isothiazolyl group, an oxazolyl group, an isoxazolyl group, a pyridinyl group, a pyrazinyl group, a pyrimidinyl group, a pyridazinyl group, an isoindolyl group, an indolyl group, an indazolyl group, a purinyl group, a quinolinyl group, an isoquinolinyl group, a benzoquinolinyl group, a quinoxalinyl group, a quinazolinyl group, a cinnolinyl group, a carbazolyl group, a phenanthrolinyl group, a benzimidazolyl group, a benzofuranyl group, a benzothiophenyl group, a benzoisothiazolyl group, a benzoxazolyl group, an isobenzoxazolyl group, a triazolyl group, a tetrazolyl group, an oxadiazolyl group, a triazinyl group, a dibenzofuranyl group, a dibenzothiophenyl group, a benzocarbazolyl group, a dibenzocarbazolyl group, an imidazopyridinyl group, an imidazopyrimidinyl group, an azacarbazolyl group, an azadibenzofuranyl group, an azadibenzothiophenyl group, or any combination thereof; or
—N(Q₁)(Q₂), —Si(Q₃)(Q₄)(Q₅), —Ge(Q₃)(Q₄)(Q₅), —B(Q₆)(Q₇), —P(═O)(Q₈)(Q₉), or —P(Q₈)(Q₉), and
Q₁ to Q₉ may each independently be:
—CH₃, —CD₃, —CD₂H, —CDH₂, —CH₂CH₃, —CH₂CD₃, —CH₂CD₂H, —CH₂CDH₂, —CHDCH₃, —CHDCD₂H, —CHDCDH₂, —CHDCD₃, —CD₂CD₃, —CD₂CD₂H, or —CD₂CDH₂; or
an n-propyl group, an iso-propyl group, an n-butyl group, a sec-butyl group, an isobutyl group, a tert-butyl group, an n-pentyl group, a tert-pentyl group, a neopentyl group, an isopentyl group, a sec-pentyl group, a 3-pentyl group, a sec-isopentyl group, a phenyl group, a biphenyl group, or a naphthyl group, each unsubstituted or substituted with deuterium, a C₁-C₂₀ alkyl group, a phenyl group, or any combination thereof.

The organometallic compound may further include a ligand, for example, —F, —Cl, —I, —Br, or acetylacetonate, in addition to the ligands represented by Formulae 2-1 to 2-4.

In an embodiment, the organometallic compound may be represented by Formula 2(1):

### Formula 2(1)

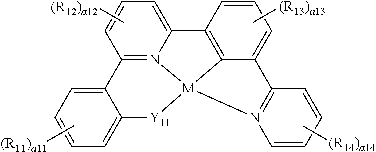

wherein, in Formula 2(1),
M is a transition metal as described in the present specification,
Y₁₁ is the same as described in the present specification,
R₁₁ to R₁₄ are each the same as described in connection with R₁₀,
a11 and a14 are each independently an integer from 0 to 4, and
a12 and a13 are each independently an integer from 0 to 3.

For example, Y₁₁ in Formula 2(1) may be O or S.

In an embodiment, A₂ in Formula 1 may be a monovalent group derived from one of Compounds PD1 to PD87 and connected to A₁, or A₃ if m1 is zero, for example a connection can be made to a ring carbon or a substituent carbon of the compounds PD1 to PD87:

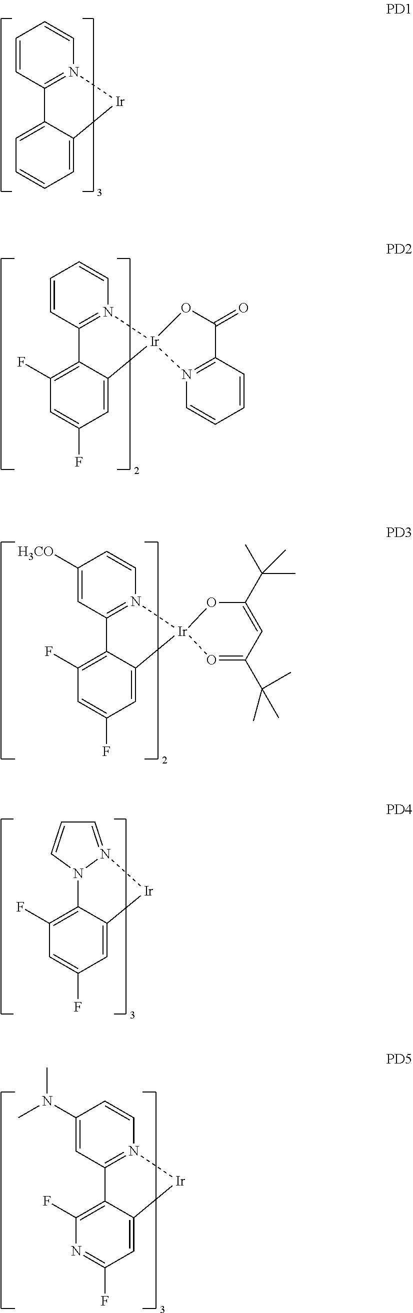

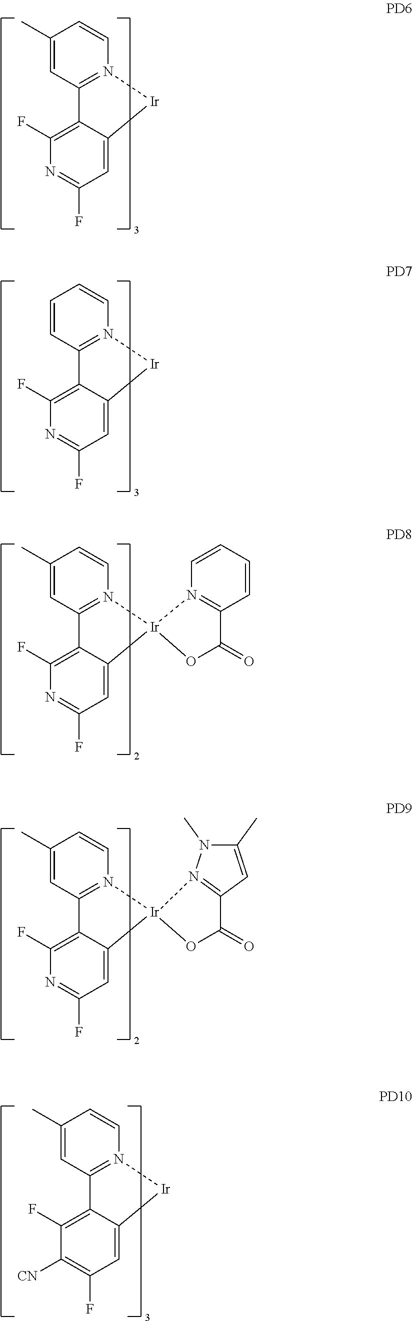

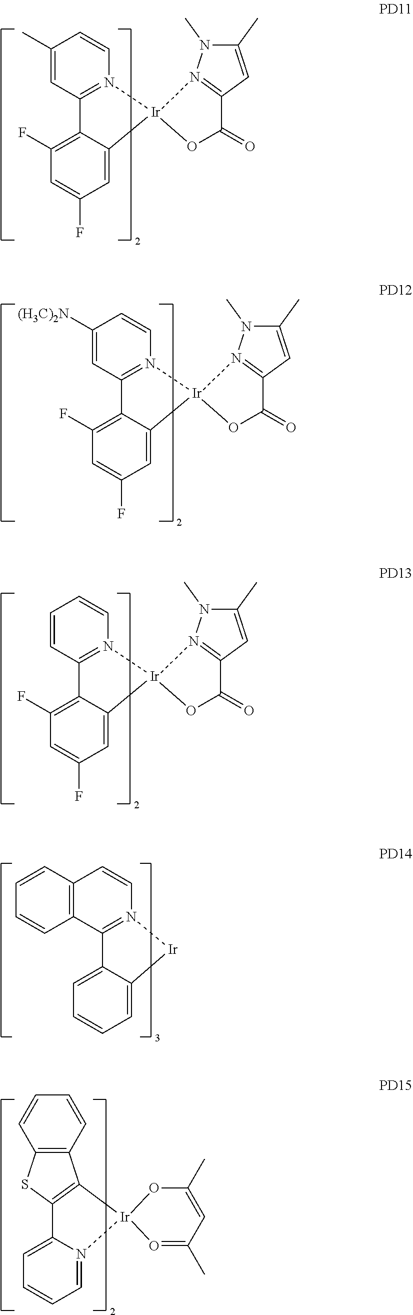

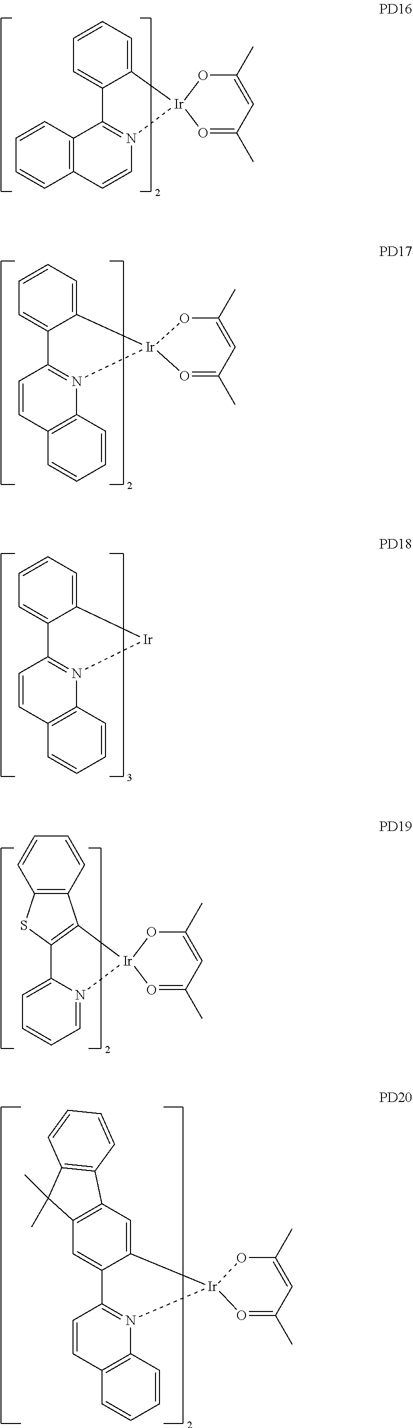

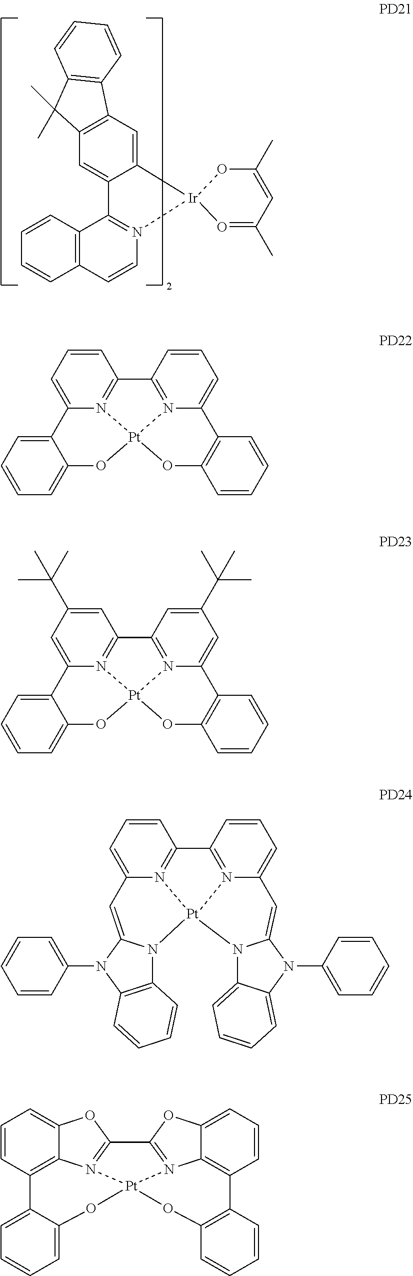

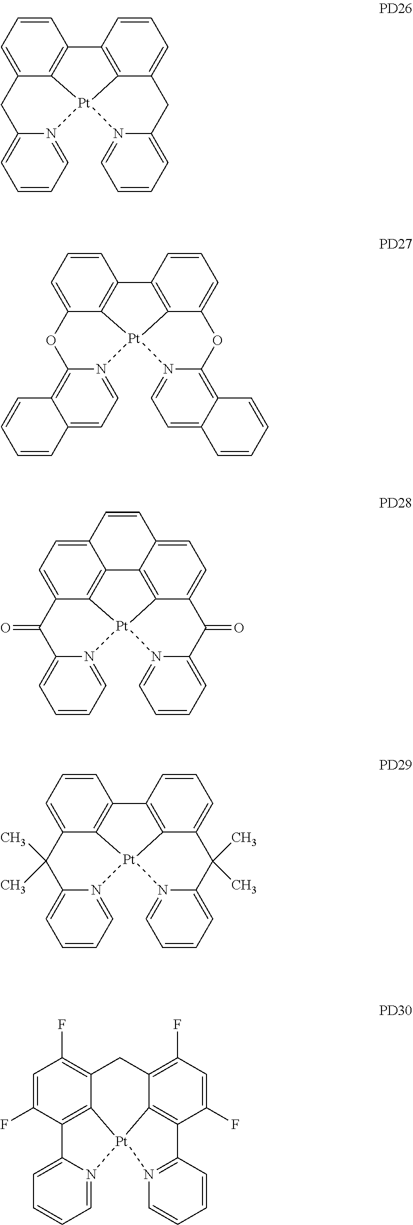

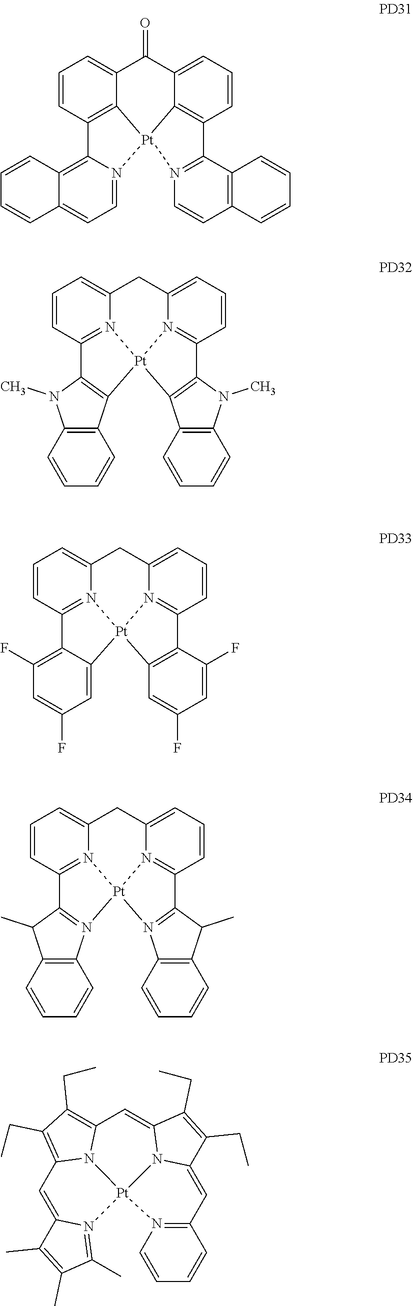

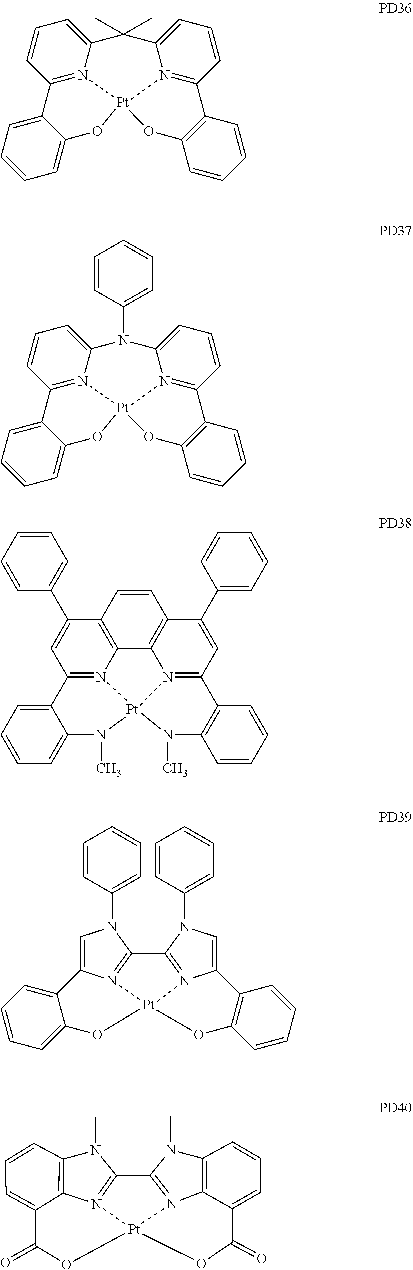

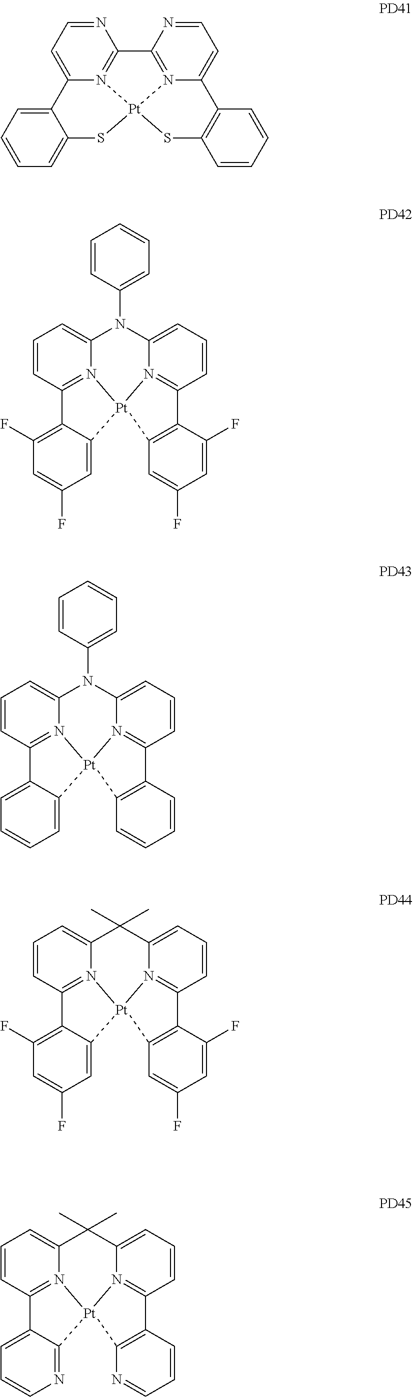

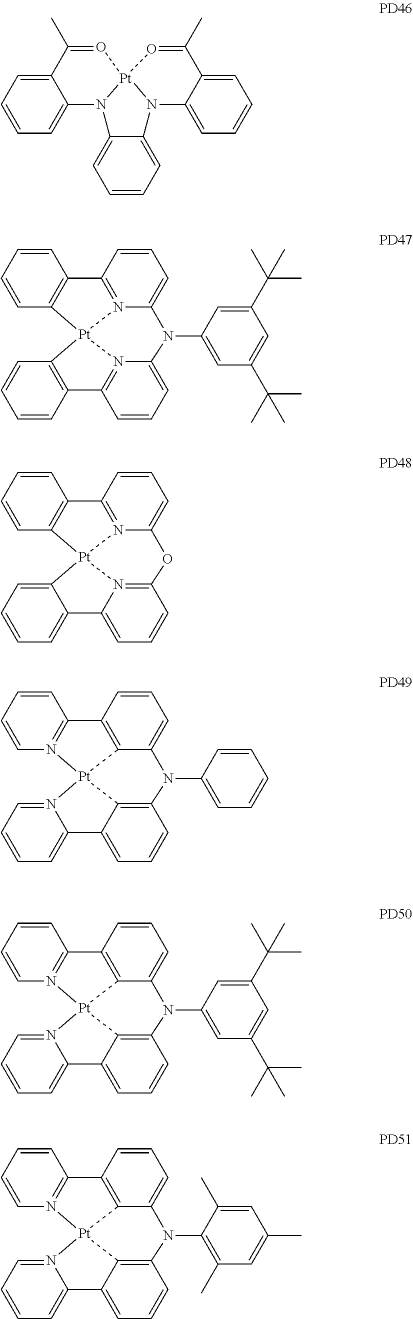

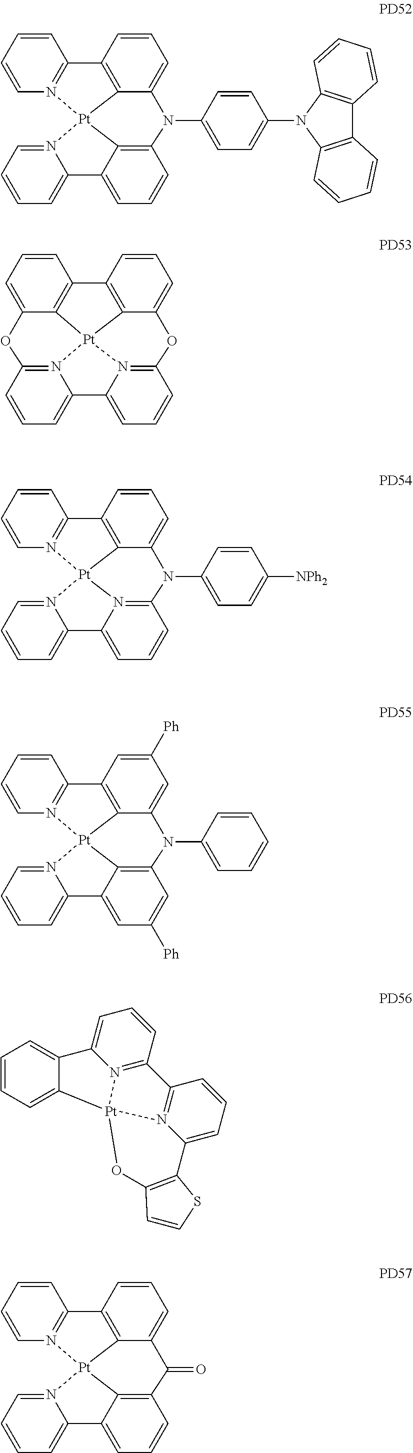

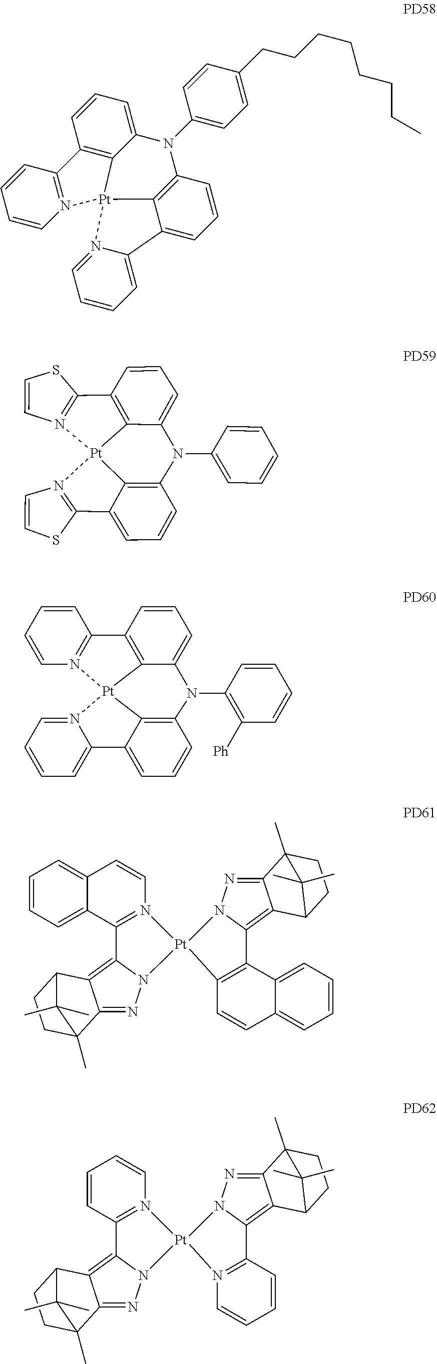

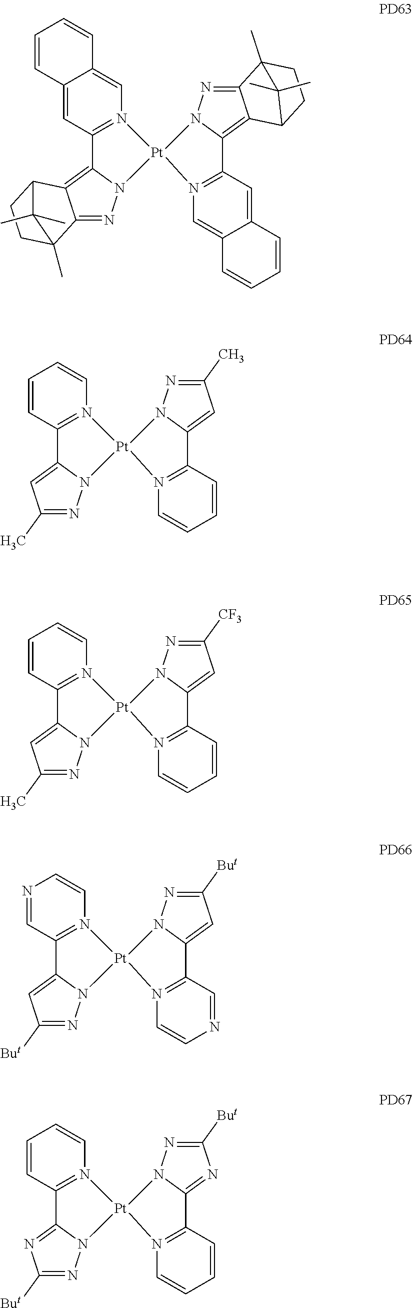

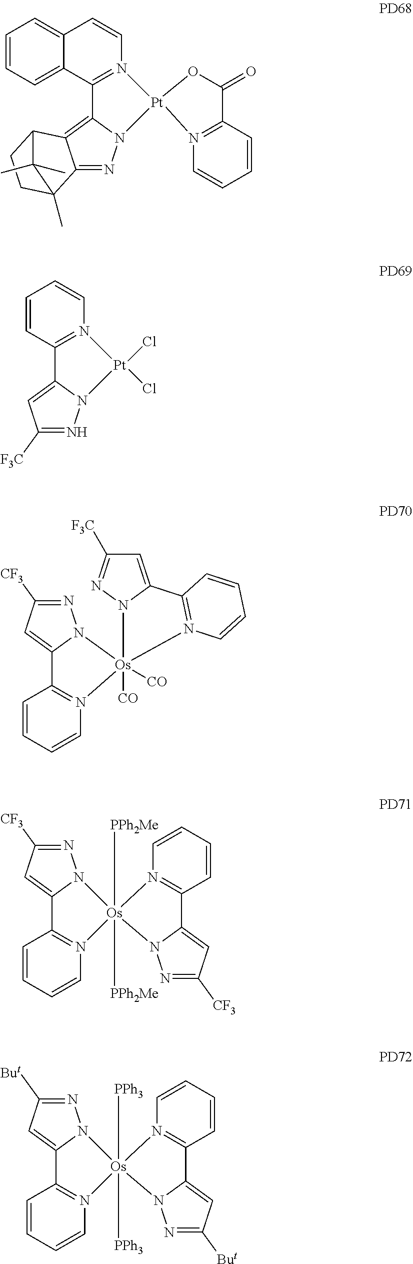

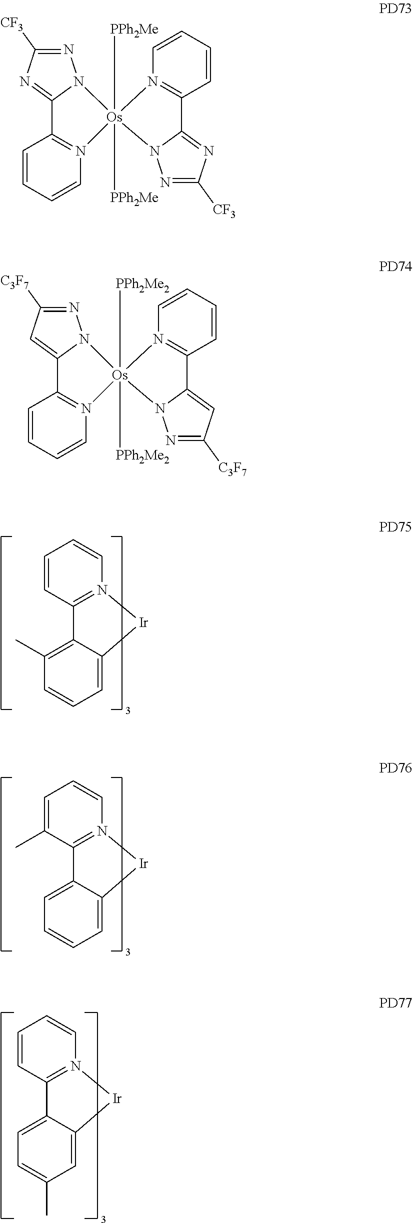

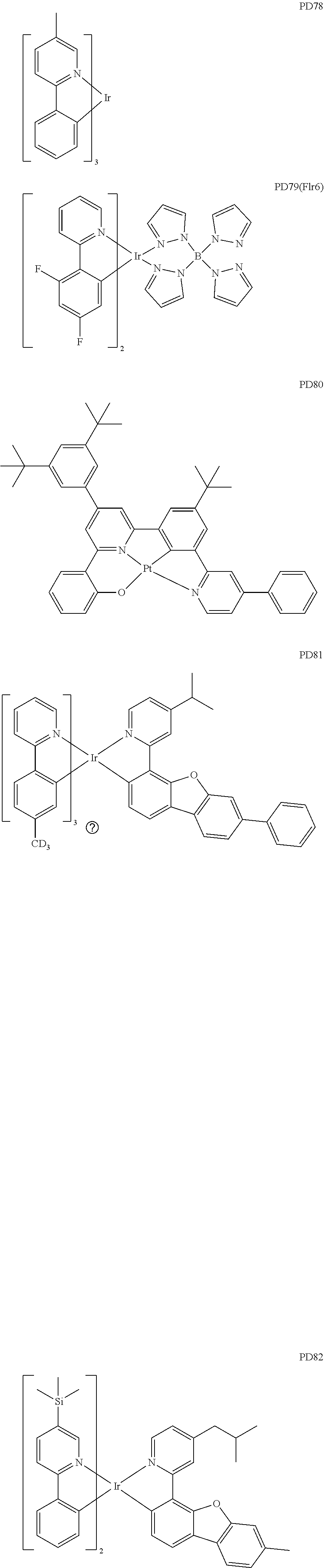

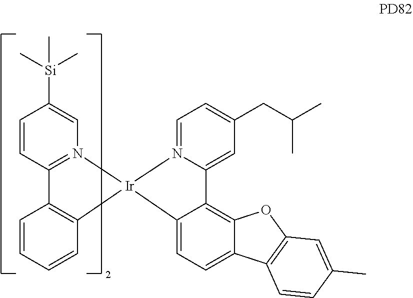

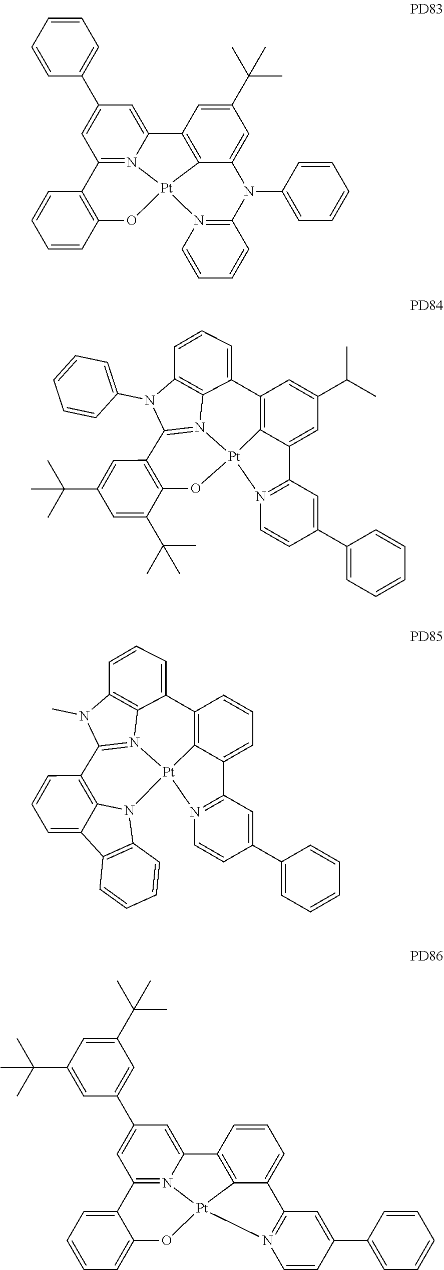

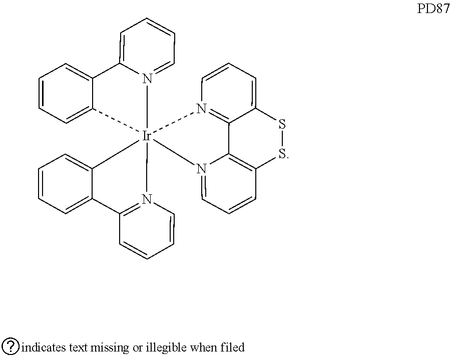

In an embodiment, A₂ in Formula 1 may be a fluorescent luminescent compound, which is a compound capable of emitting fluorescence.

The fluorescence may be prompt fluorescence, delayed fluorescence, or the like. The delayed fluorescence may be thermally activated delayed fluorescence.

In an embodiment, the fluorescent luminescent compound may be a thermally activated delayed fluorescence emitter. The thermally activated delayed fluorescence emitter may be selected from any compound that is capable of emitting delayed fluorescence according to the thermally activated delayed fluorescence emission mechanism.

A difference (absolute value) between the triplet energy level in electron Volts (eV) of the thermally activated delayed fluorescence emitter and the singlet energy level (eV) of the thermally activated delayed fluorescence emitter may be greater than or equal to 0 eV and less than or equal to 0.5 eV. When the difference between the triplet energy level (eV) of the thermally activated delayed fluorescence emitter and the singlet energy level (eV) of the thermally activated delayed fluorescence emitter satisfies the above range, the up-conversion from the triplet state to the singlet state may be effectively achieved, so that the thermally activated delayed fluorescence emitter may emit high-efficiency delayed fluorescence.

For example, the fluorescent luminescent compound may be an amino group-containing condensed cyclic compound, a compound containing a donor and an acceptor, a boron-containing compound, or the like.

For example, the fluorescent luminescent compound may be a compound represented by Formula 501:

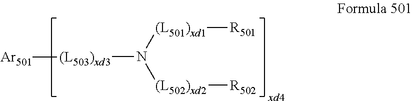

wherein, in Formula 501,
Ar₅₀₁ may be naphthalene, heptalene, fluorene, spiro-bifluorene, carbazole, benzofluorene, dibenzofluorene, phenalene, phenanthrene, anthracene, fluoranthene, triphenylene, pyrene, chrysene, naphthacene, picene, perylene, pentaphene, or indenoanthracene, each unsubstituted or substituted with at least one R₁₀ₐ,
L₅₀₁ to L₅₀₃ may each independently be a C₅-C₃₀ carbocyclic group that is unsubstituted or substituted with at least one R₁₀ₐ or a C₂-C₃₀ heterocyclic group that is unsubstituted or substituted with at least one R₁₀ₐ,
R₅₀₁ and R₅₀₂ may each independently be a phenyl group, a naphthyl group, a fluorenyl group, a spiro-bifluorenyl group, a benzofluorenyl group, a dibenzofluorenyl group, a phenanthrenyl group, an anthracenyl group, a pyrenyl group, a chrysenyl group, a pyridinyl group, a pyrazinyl group, a pyrimidinyl group, a pyridazinyl group, a quinolinyl group, an isoquinolinyl group, a quinoxalinyl group, a quinazolinyl group, a carbazolyl group, a triazinyl group, a dibenzofuranyl group, or a dibenzothiophenyl group, each unsubstituted or substituted with at least one R₁₀ₐ, wherein R₁₀ₐ is the same as described in connection with R₁₀.
xd1 to xd3 may each independently be an integer from 0 to 3, and
xd4 may be an integer from 0 to 4.

For example, xd4 in Formula 501 may be an integer from 2 to 4.

A compound represented by Formula 501 may emit prompt fluorescence.

For example, A₂ in Formula 1 may be a monovalent group derived from one of Compounds FD1 to FD14 or one of FD(1) to FD(18), and connected to A₁, or A₃ if m1 is zero, for example a connection can be made to a ring carbon or a substituent carbon of the Compounds FD1 to FD14 or one of FD(1) to FD(18):

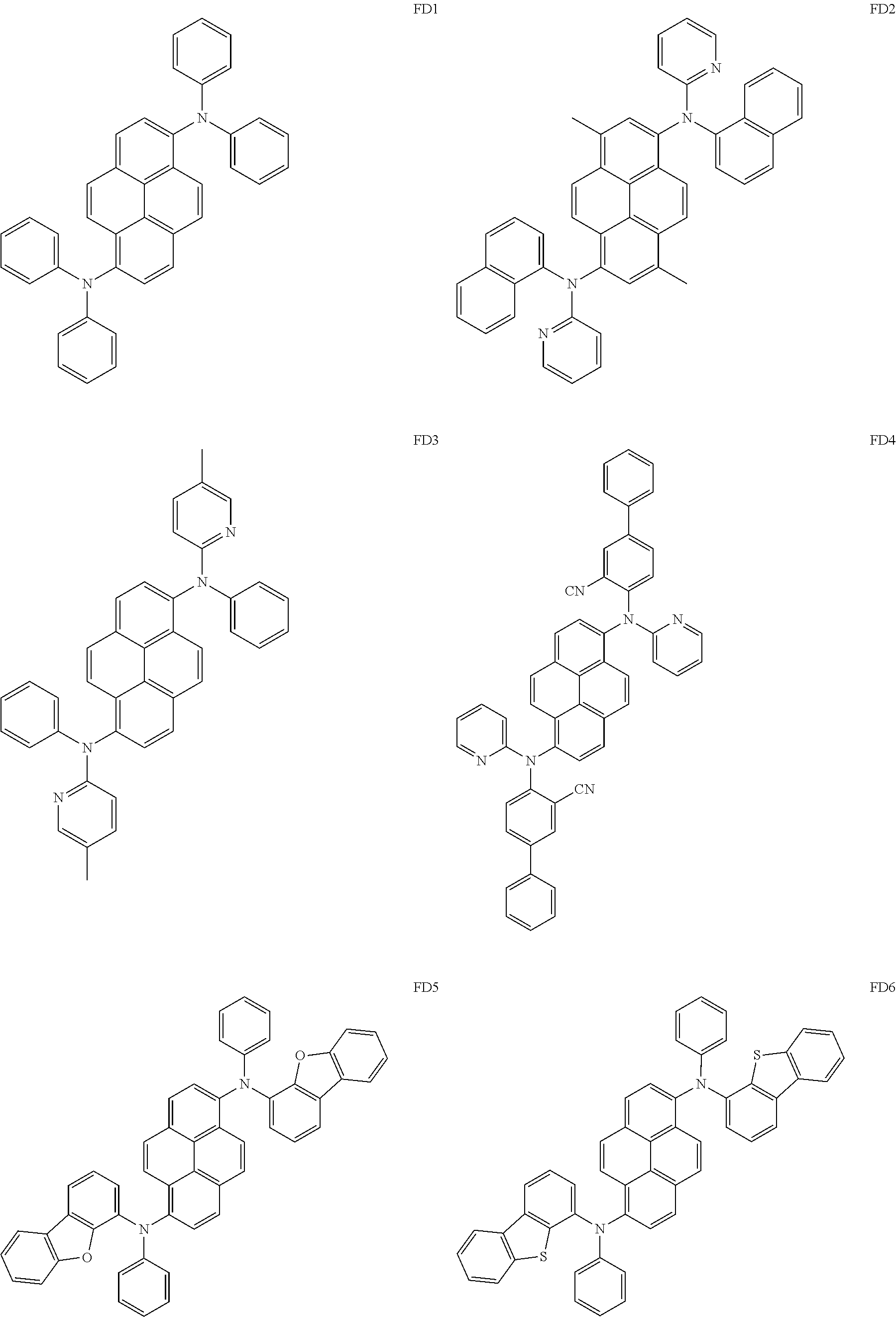

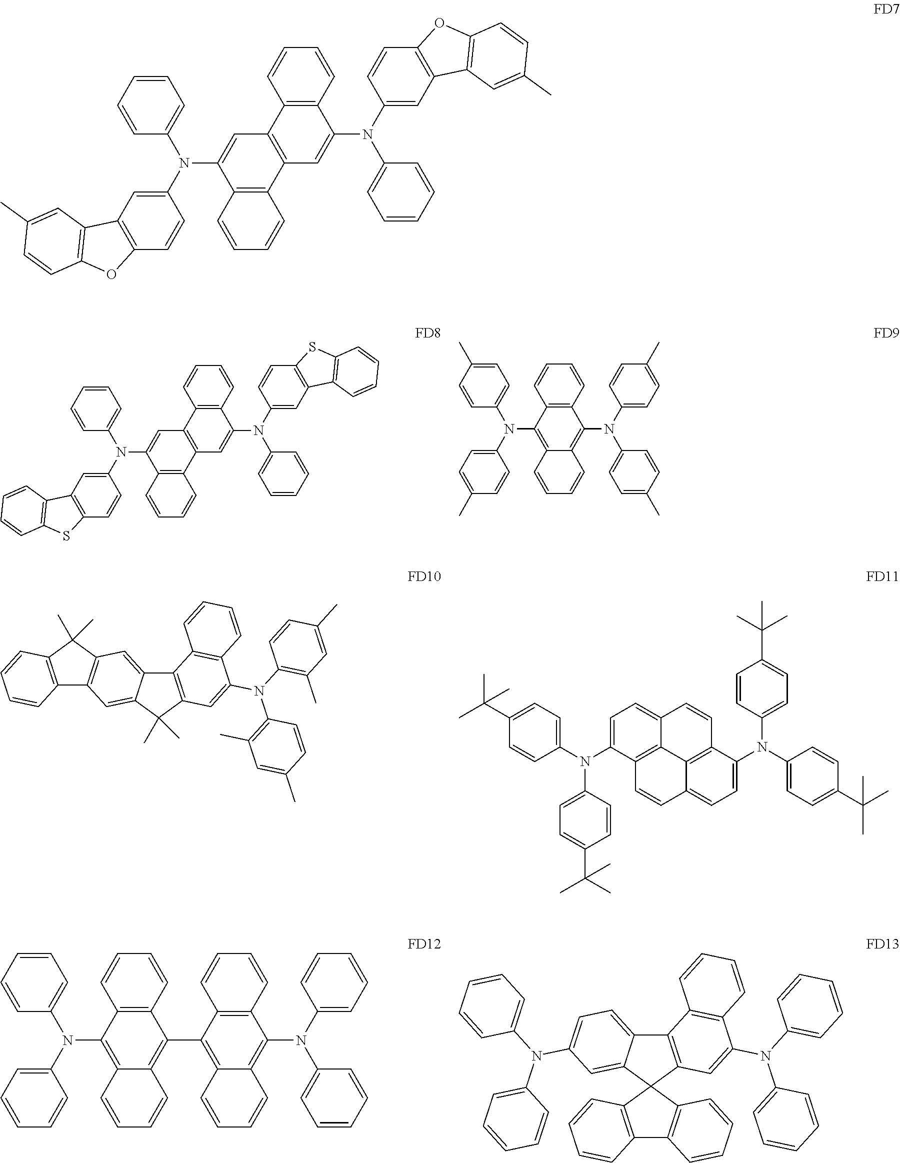

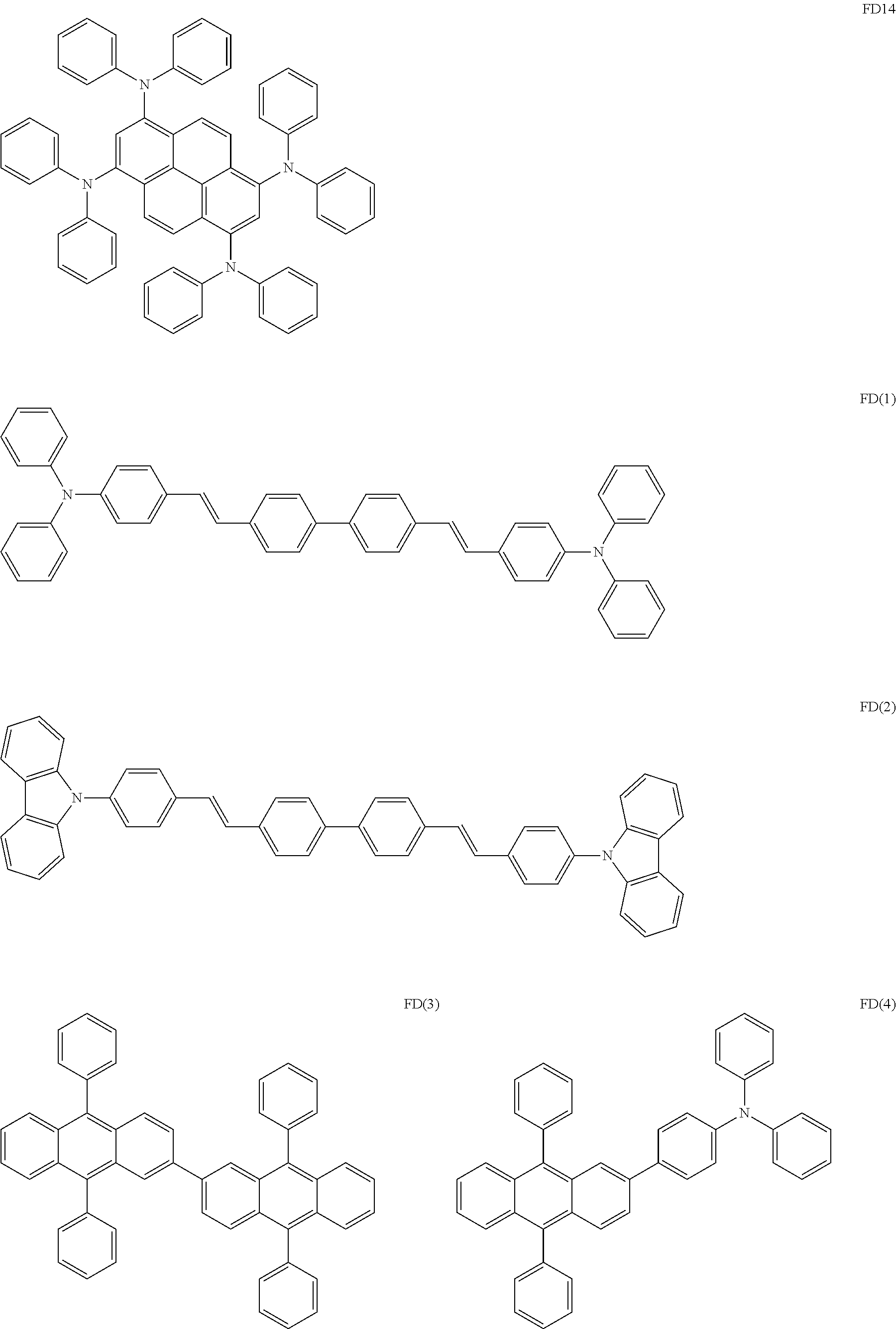

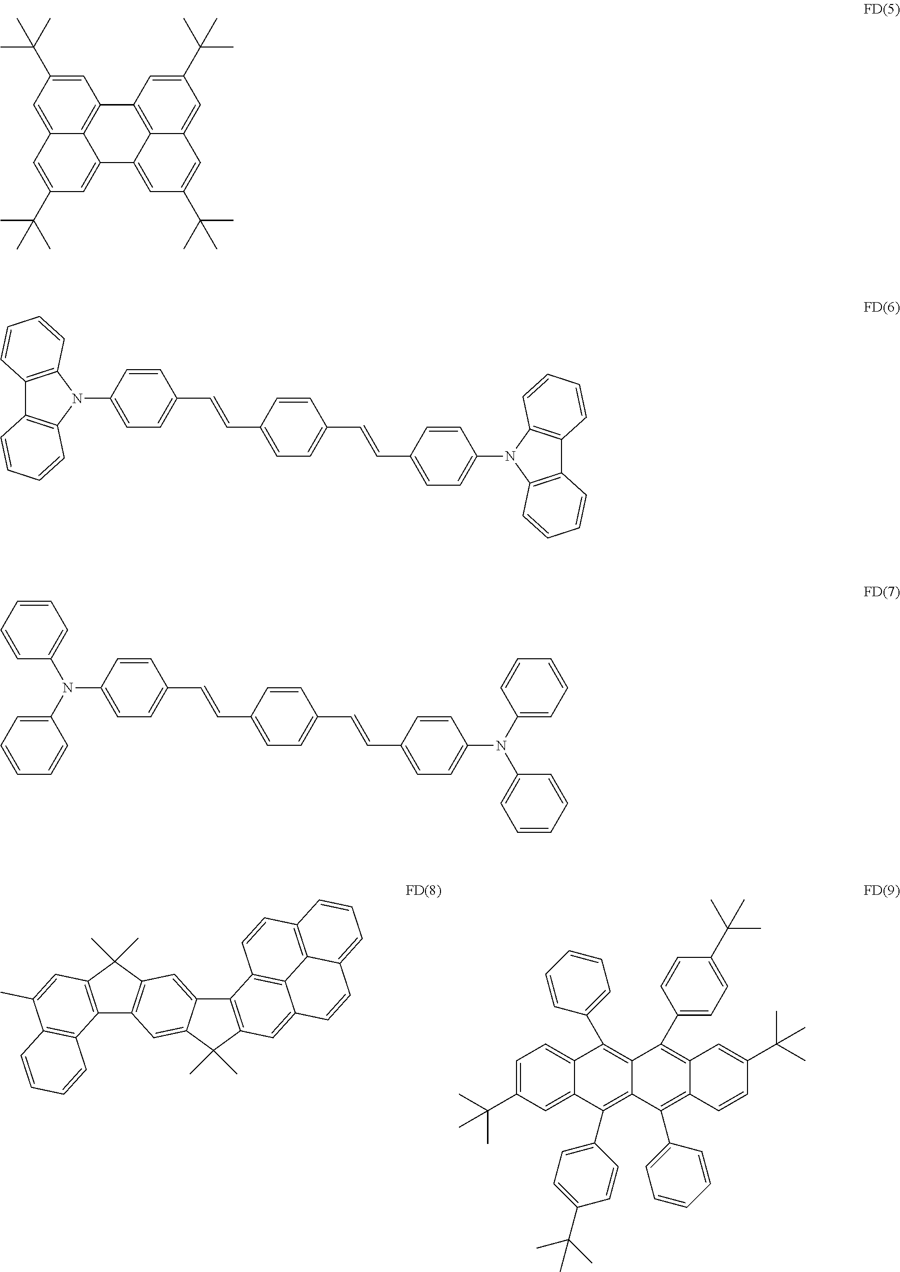

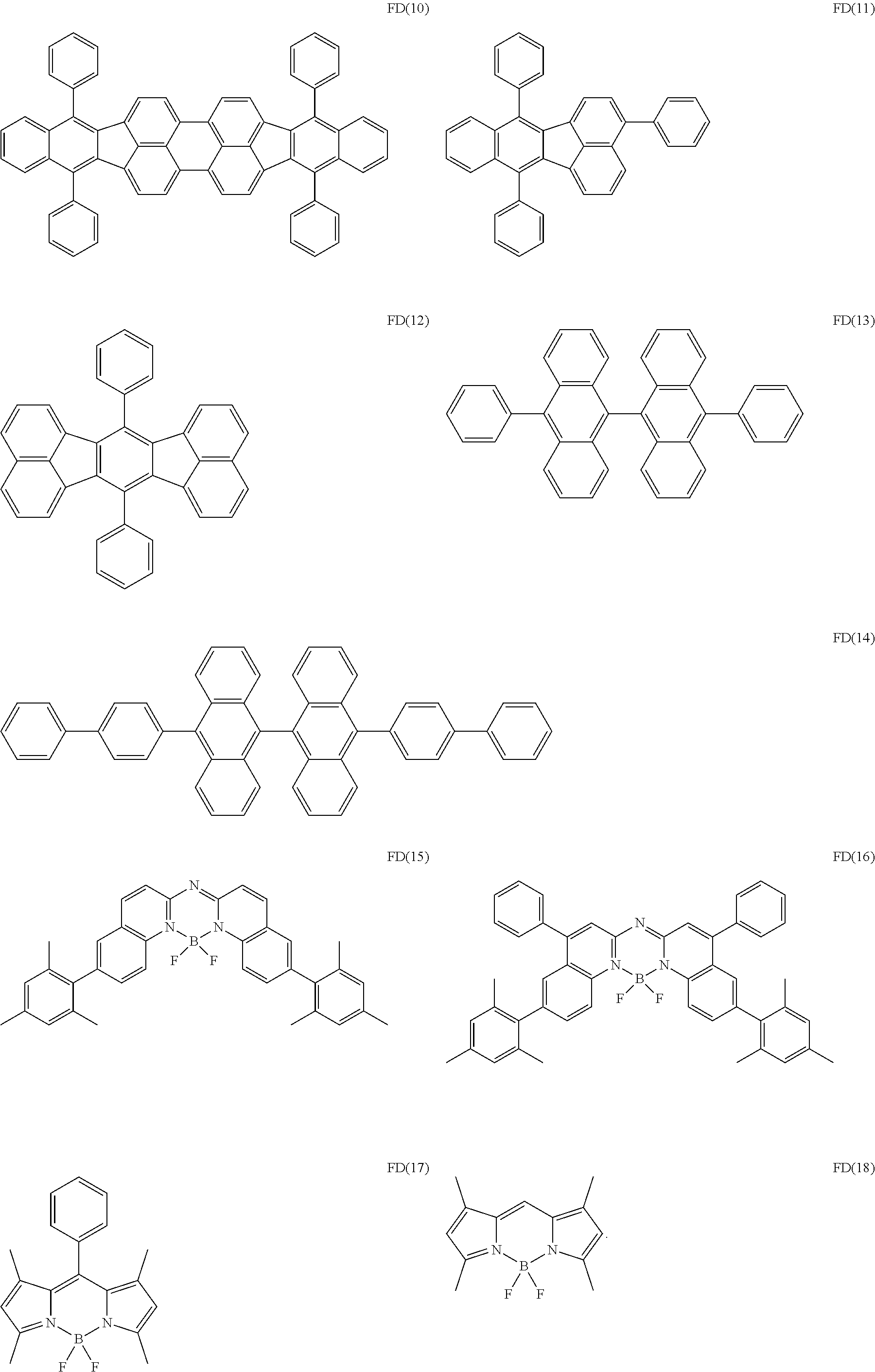

In an embodiment, the fluorescent luminescent compound may include a compound represented by Formula 11:

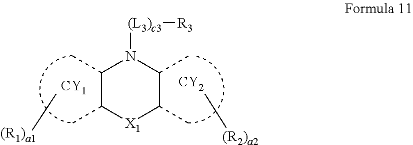

wherein, X₁ in Formula 11 may be a single bond, N-[(L₄)_{c4}-R₄], C(R₅)(R₆), O, or S. For example, X₁ may be a single bond, but the disclosure is not limited thereto.

Ring CY₁ and ring CY₂ in Formula 1 may each independently be a benzene group, a naphthalene group, an indene group, an indole group, a benzofuran group, a benzothiophene group, a benzosilole group, a fluorene group, a carbazole group, a dibenzofuran group, a dibenzothiophene group, or a dibenzosilole group. For example, ring CY₁ and ring CY₂ may each independently be a benzene group, a fluorene group, a carbazole group, a dibenzofuran group, a dibenzothiophene group, or a dibenzosilole group, and at least one of ring CY₁ and ring CY₂ may be a benzene group, but the disclosure is not limited thereto.

L₃ and L₄ may each independently be a C₅-C₃₀ carbocyclic group that is unsubstituted or substituted with at least one R₁₀ₐ or a C₁-C₃₀ heterocyclic group that is unsubstituted or substituted with at least one R₁₀ₐ. For example, L₃ and L₄ may each independently be a benzene group, a naphthalene group, a fluorene group, a pyridine group, a pyrimidine group, a pyrazine group, a pyridazine group, a triazine group, a quinoline group, an isoquinoline group, a carbazole group, a dibenzofuran group, a dibenzothiophene group, or an indolocarbazole group, each unsubstituted or substituted with at least one R₁₀ₐ.

c3 and c4 indicate the number of L₃ and the number of L₄, respectively, and may each independently be an integer of 0 to 4. When c3 is 2 or more, two or more L₃(s) may be the same or different from each other, and when c4 is 2 or more, two or more L₄(s) may be the same or different from each other. For example, c3 and c4 may each independently be 0, 1, or 2, but the disclosure is not limited thereto. When c3 is 0, *—(L₃)_{c3}—*′ may be a single bond, and when c4 is 0, *—(L₄)_{c4}—*′ may be a single bond.

R₁ to R₆ in Formula 11 are each the same as described in connection with R₁₀.

In an embodiment, R₃ in Formula 11 may include at least one π electron-deficient nitrogen-containing cyclic group.

The term “π electron-deficient nitrogen-containing cyclic group” refers to a group including a cyclic group having at least one *—N═*′ moiety, and for example, the π electron-deficient nitrogen-containing cyclic group may be an imidazole group, a pyrazole group, a thiazole group, an isothiazole group, an oxazole group, an isoxazole group, a pyridine group, a pyrazine group, a pyridazine group, a pyrimidine group, an indazole group, a purine group, a quinoline group, an isoquinoline group, a benzoquinoline group, a benzoisoquinolic, a phthalazine group, a naphthyridine group, a quinoxaline group, a benzoquinoxaline group, a quinazoline group, a cinnoline group, a phenanthridine group, an acridine group, a phenanthroline group, a phenazine group, a benzimidazole group, an iso-benzothiazole group, a benzoxazole group, a benzoisoxazole group, a triazole group, a tetrazole group, an oxadiazole group, a triazine group, a thiadiazole group, an imidazopyridine group, an imidazopyrimidine group, an azaindene group, an azaindole group, an azabenzofuran group, an azabenzothiophene group, an azabenzosilole group, an azafluorene group, an azacarbazole group, an azadibenzofuran group, an azadibenzothiophene group, or an azadibenzosilole group.

In an embodiment, R₃ in Formula 11 may be:
a phenyl group, an indenyl group, a naphthyl group, a fluorenyl group, a spiro-bifluorenyl group, a benzofluorenyl group, a dibenzofluorenyl group, a phenanthrenyl group, an anthracenyl group, a fluoranthenyl group, a triphenylenyl group, a pyrenyl group, a chrysenyl group, a pyrrolyl group, an isoindolyl group, an indolyl group, a furanyl group, a thiophenyl group, a silolyl group, a benzofuranyl group, a benzothiophenyl group, a benzosilolyl group, a carbazolyl group, a dibenzofuranyl group, a dibenzothiophenyl group, a dibenzosilolyl group, an indeno carbazolyl group, an indolocarbazolyl group, a benzofuracarbazolyl group, a benzothienocarbazolyl group, a benzosilolocarbazolyl group, an imidazolyl group, a pyrazolyl group, a thiazolyl group, an isothiazolyl group, an oxazolyl group, an isoxazolyl group, a pyridinyl group, a pyrazinyl group, a pyridazinyl group, a pyrimidinyl group, an indazolyl group, a purinyl group, a quinolinyl group, an isoquinolinyl group, a benzoquinolinyl group, a benzoisoquinolinyl group, a phthalazinyl group, a naphthyridinyl group, a quinoxalinyl group, a benzoquinoxalinyl group, a quinazolinyl group, a cinnolinyl group, a phenanthridinyl group, an acridinyl group, a phenanthrolinyl group, a phenazinyl group, a benzimidazolyl group, a benzoisothiazolyl group, a benzoxazolyl group, an isobenzoxazolyl group, a triazolyl group, a tetrazolyl group, an oxadiazolyl group, a triazinyl group, a thiadiazolyl group, an imidazopyridinyl group, an imidazopyrimidinyl group, an azaindenyl group, an azaindolyl group, an azabenzofuranyl group, an azabenzothiophenyl group, an azabenzosilolyl group, an azafluorenyl group, an azacarbazolyl group, an azadibenzofuranyl group, an azadibenzothiophenyl group, or an azadibenzosilolyl group, each unsubstituted or substituted with deuterium, a C₁-C₁₀ alkyl group, a C₁-C₁₀ alkoxy group, a phenyl group, a (C₁-C₁₀ alkyl)phenyl group, a di(C₁-C₁₀ alkyl)phenyl group, a biphenyl group, a terphenyl group, a di(phenyl)phenyl group, a di(biphenyl)phenyl group, a (pyridinyl)phenyl group, a di(pyridinyl)phenyl group, a (pyrimidinyl)phenyl group, a di(pyrimidinyl)phenyl group, a (triazinyl)phenyl group, a di(triazinyl)phenyl group, a pyridinyl group, a (C₁-C₁₀ alkyl)pyridinyl group, a di(C₁-C₁₀ alkyl)pyridinyl group, a (phenyl)pyridinyl group, a di(phenyl)pyridinyl group, a (biphenyl)pyridinyl group, a di(biphenyl)pyridinyl group, a (terphenyl)pyridinyl group, a bi(terphenyl)pyridinyl group, a (pyridinyl)pyridinyl group, a di(pyridinyl)pyridinyl group, a (pyrimidinyl)pyridinyl group, a di(pyrimidinyl)pyridinyl group, a (triazinyl)pyridinyl group, a di(triazinyl)pyridinyl group, a pyrimidinyl group, a (C₁-C₁₀ alkyl)pyrimidinyl group, a di(C₁-C₁₀ alkyl)pyrimidinyl group, a (phenyl)pyrimidinyl group, a di(phenyl)pyrimidinyl group, a (biphenyl)pyrimidinyl group, a di(biphenyl)pyrimidinyl group, a (terphenyl)pyrimidinyl group, a bi(terphenyl)pyrimidinyl group, a (pyridinyl)pyrimidinyl group, a di(pyridinyl)pyrimidinyl group, a (pyrimidinyl)pyrimidinyl group, a di(pyrimidinyl)pyrimidinyl group, a (triazinyl)pyrimidinyl group, a di(triazinyl)pyrimidinyl group, a triazinyl group, a (C₁-C₁₀ alkyl)triazinyl group, a di(C₁-C₁₀ alkyl)triazinyl group, a (phenyl)triazinyl group, a di(phenyl)triazinyl group, a (biphenyl)triazinyl group, a di(biphenyl)triazinyl group, a (terphenyl)triazinyl group, a bi(terphenyl)triazinyl group, a (pyridinyl)triazinyl group, a di(pyridinyl)triazinyl group, a (pyrimidinyl)triazinyl group, a di(pyrimidinyl)triazinyl group, a (triazinyl)triazinyl group, a di(triazinyl)triazinyl group, a fluorenyl group, a di (C₁-C₁₀ alkyl)fluorenyl group, a di(phenyl)fluorenyl group, a di(biphenyl)fluorenyl group, a carbazolyl group, a (C₁-C₁₀ alkyl)carbazolyl group, a (phenyl)carbazolyl group, a (biphenyl)carbazolyl group, a dibenzofuranyl group, a (C₁-C₁₀ alkyl)dibenzofuranyl group, a (phenyl)dibenzofuranyl group, a (biphenyl)dibenzofuranyl group, a dibenzothiophenyl group, a (C₁-C₁₀ alkyl)dibenzothiophenyl group, a (phenyl)dibenzothiophenyl group, a (biphenyl)dibenzothiophenyl group, or any combination thereof.

In an embodiment, the fluorescent luminescent compound may include a compound represented by Formula 14A:

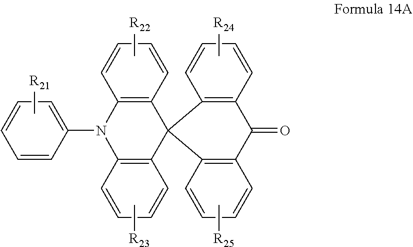

wherein R₂₁ to R₂₅ in Formula 14A may each independently be hydrogen, deuterium, a cyano group, a C₁-C₁₀ alkyl group, a phenyl group, a biphenyl group, or a terphenyl group.

In an embodiment, A₂ in Formula 1 may be a monovalent group derived from one of Compounds D1-1 to D1-20, and connected to A₁, or A₃ if m1 is zero, for example a connection can be made to a ring carbon of the Compounds D1-1 to D1-20:

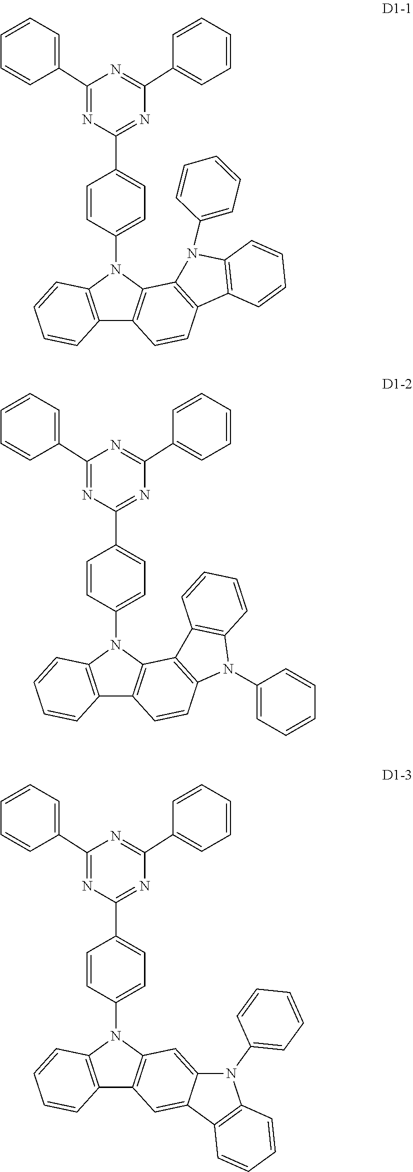 [SMILES: c1ccc(-c2nc(-c3ccccc3)nc(-c3ccc(-n4c5ccccc5c5ccc6c7ccccc7n(-c7ccccc7)c6c54)cc3)n2)cc1 ; c1ccc(-c2nc(-c3ccccc3)nc(-c3ccc(-n4c5ccccc5c5ccc6c(c7ccccc7n6-c6ccccc6)c54)cc3)n2)cc1 ; c1ccc(-c2nc(-c3ccccc3)nc(-c3ccc(-n4c5ccccc5c5cc6c7ccccc7n(-c7ccccc7)c6cc54)cc3)n2)cc1]

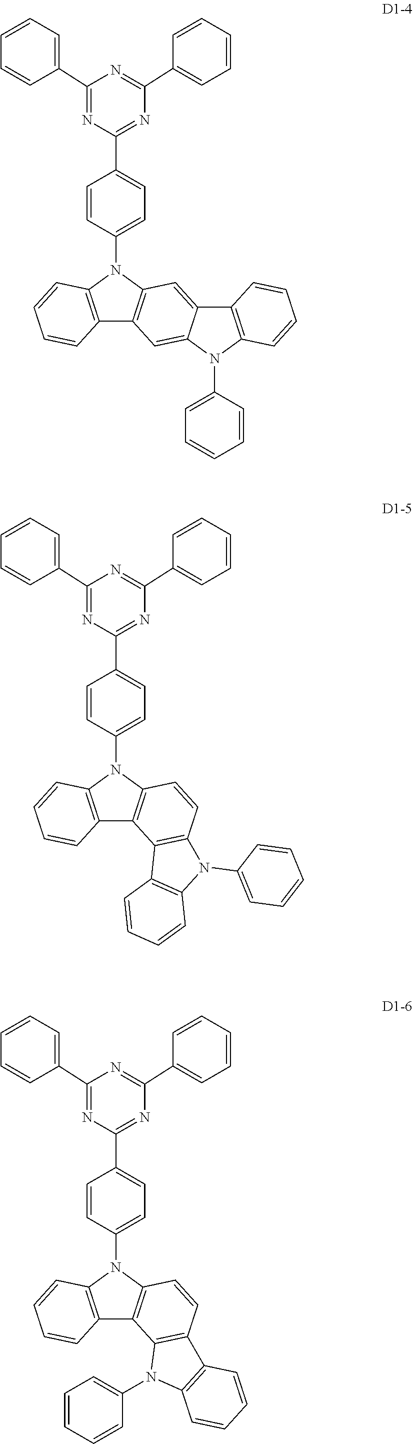 [SMILES: c1ccc(-c2nc(-c3ccccc3)nc(-c3ccc(-n4c5ccccc5c5cc6c(cc54)c4ccccc4n6-c4ccccc4)cc3)n2)cc1 ; c1ccc(-c2nc(-c3ccccc3)nc(-c3ccc(-n4c5ccccc5c5c6c7ccccc7n(-c7ccccc7)c6ccc54)cc3)n2)cc1 ; c1ccc(-c2nc(-c3ccccc3)nc(-c3ccc(-n4c5ccccc5c5c4ccc4c6ccccc6n(-c6ccccc6)c45)cc3)n2)cc1]

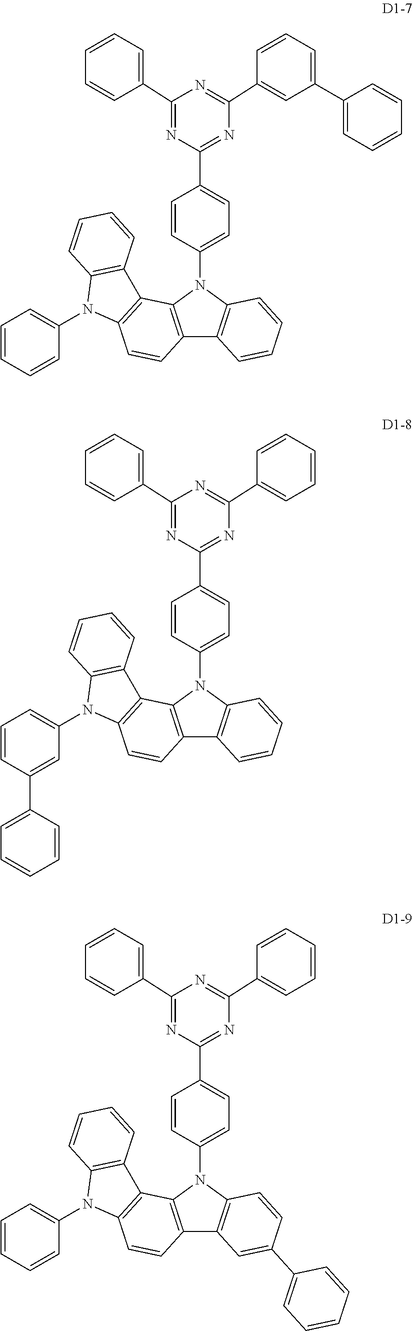 [SMILES: c1ccc(-c2cccc(-c3nc(-c4ccccc4)nc(-c4ccc(-n5c6ccccc6c6ccc7c(c8ccccc8n7-c7ccccc7)c65)cc4)n3)c2)cc1 ; c1ccc(-c2cccc(-n3c4ccccc4c4c3ccc3c5ccccc5n(-c5ccc(-c6nc(-c7ccccc7)nc(-c7ccccc7)n6)cc5)c34)c2)cc1 ; c1ccc(-c2ccc3c(c2)c2ccc4c(c5ccccc5n4-c4ccccc4)c2n3-c2ccc(-c3nc(-c4ccccc4)nc(-c4ccccc4)n3)cc2)cc1]

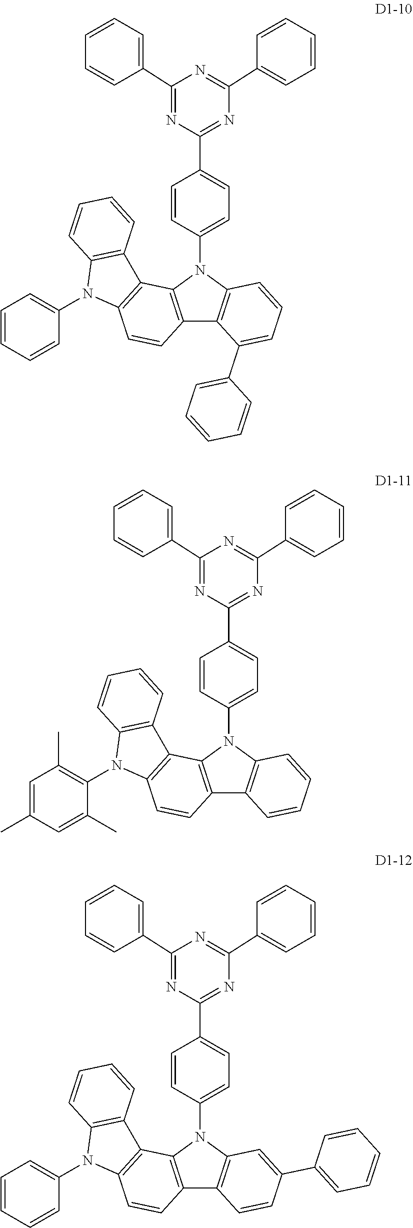 [SMILES: c1ccc(-c2nc(-c3ccccc3)nc(-c3ccc(-n4c5cccc(-c6ccccc6)c5c5ccc6c(c7ccccc7n6-c6ccccc6)c54)cc3)n2)cc1 ; Cc1cc(C)c(-n2c3ccccc3c3c2ccc2c4ccccc4n(-c4ccc(-c5nc(-c6ccccc6)nc(-c6ccccc6)n5)cc4)c23)c(C)c1 ; c1ccc(-c2ccc3c4ccc5c(c6ccccc6n5-c5ccccc5)c4n(-c4ccc(-c5nc(-c6ccccc6)nc(-c6ccccc6)n5)cc4)c3c2)cc1]

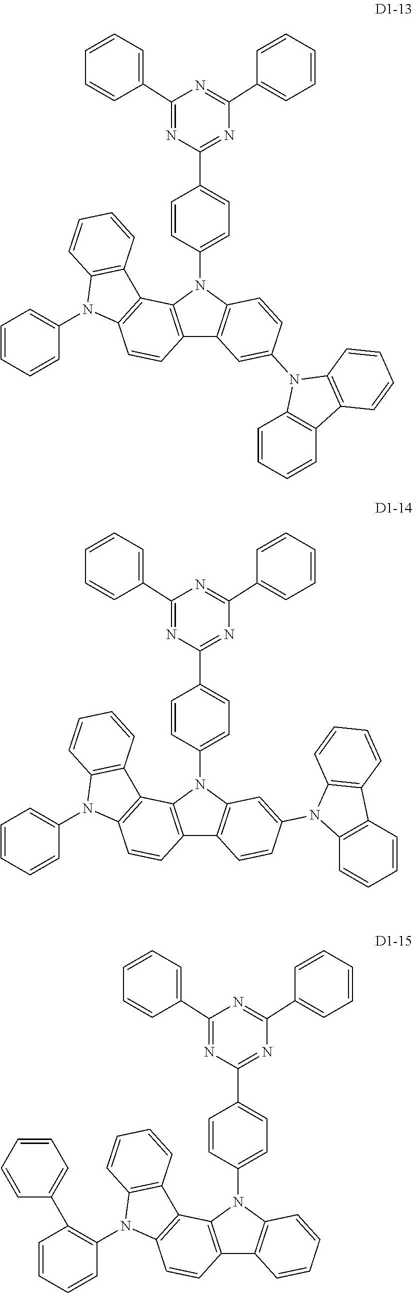 [SMILES: c1ccc(-c2nc(-c3ccccc3)nc(-c3ccc(-n4c5ccc(-n6c7ccccc7c7ccccc76)cc5c5ccc6c(c7ccccc7n6-c6ccccc6)c54)cc3)n2)cc1 ; c1ccc(-c2nc(-c3ccccc3)nc(-c3ccc(-n4c5cc(-n6c7ccccc7c7ccccc76)ccc5c5ccc6c(c7ccccc7n6-c6ccccc6)c54)cc3)n2)cc1 ; c1ccc(-c2nc(-c3ccccc3)nc(-c3ccc(-n4c5ccccc5c5ccc6c(c7ccccc7n6-c6ccccc6-c6ccccc6)c54)cc3)n2)cc1]

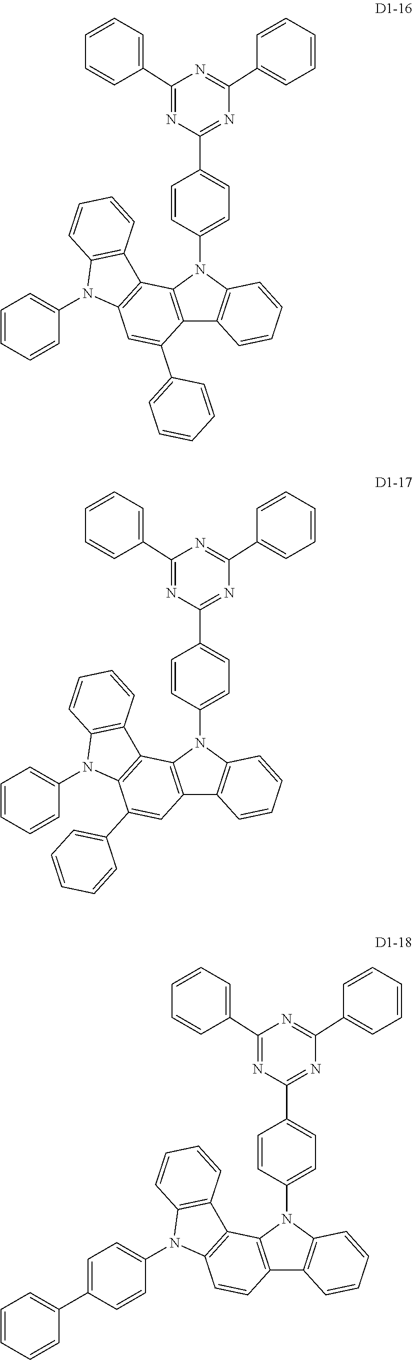 [SMILES: c1ccc(-c2nc(-c3ccccc3)nc(-c3ccc(-n4c5ccccc5c5c(-c6ccccc6)cc6c(c7ccccc7n6-c6ccccc6)c54)cc3)n2)cc1 ; c1ccc(-c2nc(-c3ccccc3)nc(-c3ccc(-n4c5ccccc5c5cc(-c6ccccc6)c6c(c7ccccc7n6-c6ccccc6)c54)cc3)n2)cc1 ; c1ccc(-c2ccc(-n3c4ccccc4c4c3ccc3c5ccccc5n(-c5ccc(-c6nc(-c7ccccc7)nc(-c7ccccc7)n6)cc5)c34)cc2)cc1]

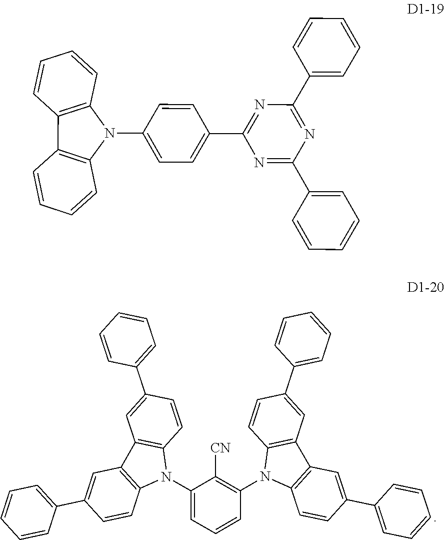 [SMILES: c1ccc(-c2nc(-c3ccccc3)nc(-c3ccc(-n4c5ccccc5c5ccccc54)cc3)n2)cc1 ; N#Cc1c(-n2c3ccc(-c4ccccc4)cc3c3cc(-c4ccccc4)ccc32)cccc1-n1c2ccc(-c3ccccc3)cc2c2cc(-c3ccccc3)ccc21]

In an embodiment, A₂ in Formula 1 may be a monovalent group derived from a quantum dot.

The quantum dot refers to a crystal of a semiconductor compound and may include all materials that emit different lengths of emission wavelengths depending on the size of the crystal. A diameter of the quantum dot may be, for example, in a range of about 1 nm to about 30 nm.

The quantum dot may be: a Group III-VI semiconductor compound; a Group II-VI semiconductor compound; a Group III-V semiconductor compound; a Group IV-VI semiconductor compound; a Group IV element or compound; or any combination thereof.

For example, the Group III-VI semiconductor compound may include: a binary compound, such as In₂S₃; a ternary compound, such as AgInS, AgInS₂, CuInS, or CuInS₂; or any combination thereof.

For example, the Group II-VI semiconductor compound may include: a binary compound, such as CdSe, CdTe, ZnS, ZnSe, ZnTe, ZnO, HgS, HgSe, HgTe, MgSe, or MgS; a ternary compound, such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, or MgZnS; a quaternary compound, such as CdZnSeS, CdZnSeTe, CdZnSTe, CdHgSeS, CdHgSeTe, CdHgSTe, HgZnSeS, HgZnSeTe, or HgZnSTe; or any combination thereof.

For example, the Group III-V semiconductor compound may include: a binary compound, such as GaN, GaP, GaAs, GaSb, AlN, AlP, AlAs, AlSb, InN, InP, InAs, or InSb; a ternary compound, such as GaNP, GaNAs, GaNSb, GaPAs, GaPSb, AINP, AINAs, AINSb, AIPAs, AIPSb, InGaP, InNP, InNAs, InNSb, InPAs, InPSb, or GaAINP; a quaternary compound, such as GaAINAs, GaAINSb, GaAIPAs, GaAIPSb, GaInNP, GaInNAs, GaInNSb, GaInPAs, GaInPSb, InAINP, InAINAs, InAINSb, InAIPAs, or InAIPSb; or any combination thereof.

For example, the Group IV-VI semiconductor compound may include: a binary compound, such as SnS, SnSe, SnTe, PbS, PbSe, or PbTe; a ternary compound, such as SnSeS, SnSeTe, SnSTe, PbSeS, PbSeTe, PbSTe, SnPbS, SnPbSe, or SnPbTe; a quaternary compound, such as SnPbSSe, SnPbSeTe, or SnPbSTe; or any combination thereof.

For example, the Group IV element or compound may include: a single element compound, such as Si or Ge; a binary compound, such as SiC or SiGe; or any combination thereof.

In this regard, respective elements included in the binary compound, the ternary compound, or the quaternary compound may exist in particles at uniform concentration or may exist in the same particle in a state in which a concentration distribution is partially different.

In an embodiment, the quantum dot may have a single structure or a dual core-shell structure. In the case of the quantum dot having a single structure, the concentration of each element included in the corresponding quantum dot may be uniform. In an embodiment, the material contained in the core and the material contained in the shell may be different from each other.

The shell of the quantum dot may act as a protective layer to prevent chemical degeneration of the core to maintain semiconductor characteristics and/or as a charging layer to impart electrophoretic characteristics to the quantum dot. The shell may be a single layer or a multi-layer. The element presented in the interface between the core and the shell of the quantum dot may have a concentration gradient that decreases toward the center of the quantum dot.

Examples of the shell of the quantum dot may include an oxide of metal or non-metal, a semiconductor compound, or any combination thereof. For example, the oxide of metal or non-metal may include: a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO; or a ternary compound, such as MgAl₂O₄, CoFe₂O₄, NiFe₂O₄, or CoMn₂O₄, but the disclosure is not limited thereto. For example, examples of the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AIAs, AIP, and AlSb, but the disclosure is not limited thereto.

The quantum dot may be a spherical particle, a pyramidal particle, a multi-arm particle, a cubic nanoparticle, a nanotube particle, a nanowire particle, a nanofiber particle, or a nanoplate particle, but the disclosure is not limited thereto.

In an embodiment, m1 and m2 in Formula 1 indicate the number of A₁ groups and the number of A₂ groups, respectively, and may each independently be an integer from 1 to 10. When m1 is 2 or more, two or more A₁ groups may be the same or different from each other, and when m2 is 2 or more, two or more A₂ groups may be the same or different from each other. For example, m1 may be an integer from 1 to 5, and m2 may be 1 or 2.

As provided in the schematic representation of FIG. 1, the plurality of light-emitting groups 13 of Formula 1 of the light-emitting device 10 is connected to the first connection layer 11 and some or most of groups A₂ of the light-emitting groups 13 of Formula 1 are arranged in an interlayer 15, e.g., at a distance from the first conducting layer in a direction toward the second conductive layer 19, but the disclosure is not limited thereto. For example, at least some of A2 groups of the light-emitting groups 13 may form what is referred to in the art as a monolayer within the interlayer 15.

In addition, the second conductive layer 19 is referred to as a layer, but the shape thereof is not necessarily limited to the layer. For example, the shape of the second conductive layer 19 may be a rod shape.

The first conductive layer 11 may be an anode, and the second conductive layer 19 may be a cathode. For example, a material for forming the second conductive layer 19 may be metal, an alloy, an electrically conductive compound, or a combination thereof, each of which has a relatively low work function. Examples of the material for forming the second conductive layer 19 may include Li, Mg, Al, Al-Li, Ca, Mg-In, or Mg-Ag.

The interlayer 15 may include an inorganic salt. The inorganic salt may be, for example, a water-soluble inorganic salt that is ionized in an aqueous solution, but the disclosure is not limited thereto. In an embodiment, the inorganic salt may be an electrolyte that may be used in various batteries.

As a cation of the inorganic salt, a monovalent cation, a divalent cation, or a trivalent cation may be appropriately used, and examples thereof may include Na⁺, K⁺, H⁺, Ca²⁺, and Mg²⁺. As an anion of the inorganic salt, a monovalent anion, a divalent anion, or a trivalent anion may be appropriately used, and examples thereof may include ClO₄₋, PF₆₋, F⁻, Cl⁻, OH⁻, and SO₄²⁻. Examples of the inorganic salt may include NaClO₄, NaF, Na₂SO₄, KF, or KOH.

The interlayer used herein includes the plurality of light-emitting groups represented by Formula 1, and the light-emitting groups include a luminescent moiety represented by A₂. The luminescent moiety A₂ may be excited by absorbing external energy and may emit the excited energy in the form of light. As represented by Formula 1, luminescent moiety A₂ may be bound to the first conductive layer 11 via a conjugate or linker, *—A₃—(A₁)ₘ₁—*′, wherein *, A₃, A₁, and m1 is as defined in Formula 1, and *′ indicates a chemical binding site to A₂.

In an embodiment, in the light-emitting device according to an embodiment, as a voltage applied to the first conductive layer and/or the second conductive layer is changed, the intensity of light emitted from the light-emitting group represented by Formula 1 may also be change, and in certain instances, the change may be significant.

For example, when a positive potential is applied to the first conductive layer, the HOMO energy level and electron density of the conjugate, *—A₃—(A₁)ₘ₁—*′, may be decreased, and electron transfer from the conjugate to A₂, especially, photoinduced electron transfer (PeT), may be decreased. As a result, the preference for a fluorescence process of the luminescent moiety represented by A₂ may be increased, and intensity of fluorescence emitted from the luminescent moiety represented by A₂ may be increased.

Therefore, one or more embodiments may provide an operating method for precisely controlling the intensity of fluorescence emitted from a light-emitting device. In addition, one or more embodiments may provide a light-emitting device in which the intensity of fluorescence to be emitted can be precisely controlled.

In an embodiment, the interlayer 15 may further include, in addition to the inorganic salt:
a hole transport material, a light-emitting material, an electron transport material, or a combination thereof; or
an insulating material, air, or inert gas.

Accordingly, the interlayer 15 may help maintain the structure of the light-emitting device 10 and may facilitate charge transfer to the light-emitting group 13.

In an embodiment, the interlayer 15 may include an insulating material that is used for a pixel-defining layer, an electrolyte that is used for various batteries, or an inert gas such as air or argon gas, depending on the desired function of the interlayer.

When a voltage is applied across the first conductive layer 11 and the second conductive layer 19 of the light-emitting device 10 of FIG. 1, light may be emitted from one or more of the light-emitting groups 13 chemically bonded to the surface of the first conductive layer 11.

In an embodiment, a variance in voltage (for example, a change in intensity of voltage) applied across the first conductive layer 11 and the second conductive layer 19 of the light-emitting device 10 of FIG. 1, the electron density of the light-emitting group 13 may be changed and the electron density may be dependent upon the voltage applied.

In an embodiment, a variance in voltage applied across the first conductive layer 11 and the second conductive layer 19 of the light-emitting device 10 of FIG. 1, the intensity of light emitted from the light-emitting group 13 may vary and the intensity may be dependent upon the voltage applied.

In the light-emitting device 10 of FIG. 1, the light-emitting group 13 is chemically directly bonded to the surface of the first conductive layer 11, e.g., chemically bonded to a gold atom positioned at the surface, and thus, the intensity of light emitted from the light-emitting group 13 may be easily controlled without a change in the molecular structure of the light-emitting device 10 and/or the light-emitting group 13, by controlling the voltage applied across the first conductive layer 11 and the second conductive layer 19. In other words, light emitted from the light-emitting device 10 may be controlled by controlling the voltage applied across the first conductive layer 11 and the second conductive layer 19, in with little or no change in the chemical structure of the light-emitting group 13 and/or the structure of the light-emitting device 10. This is in contrast with a light-emitting devices in which luminescent compound molecules are randomly and/or physically stacked on an electrode via a deposition method (for example, a vacuum deposition method) and/or a coating method (for example, a spin coating method and a laser printing method), and thus, even when the voltage applied to the certain electrode is changed, the intensity and/or maximum emission wavelength of light emitted from the luminescent compound molecules is shown to change very little, if at all. Accordingly, the light-emitting device 10 may be variously applied to various displays, light sources, and monitors.

In addition, in manufacturing the light-emitting device 10 that emits light having a certain level of color purity, half-width, maximum emission wavelength, and/or intensity, there is no need to control a substituent of the light-emitting group 13 while sacrificing the heat resistance and/or electrical stability of the light-emitting group 13. In other words, the light-emitting group 13 is shown to have excellent heat resistance and electrical stability because it is chemically bonded to the surface of the first conductive layer 11, e.g., chemically bonded to a gold atom at the surface. Moreover, because the manner in which the light-emitting device 10 including the interlayer 15 including the inorganic salt and the second conductive layer 19 is manufactured, a desired color purity, half-width, maximum emission wavelength, and/or intensity of light emitted from the light-emitting group 13 may be achieved by controlling the voltage applied across the first conductive layer 11 and the second conductive layer 19. Moreover, as a result of the improved heat resistance and/or electrical stability of the light-emitting group 13, the lifespan of the light-emitting device 10 of FIG. 1 may be increased, along with the light emitted from the light-emitting device 10 being easily controlled.

A method of manufacturing the light-emitting device 10 of FIG. 1 may include:
providing the first conductive layer 11, the first conductive layer comprising gold;
chemically bonding the light-emitting group 13 represented by Formula 1 to a surface of the first conductive layer 11 by bringing the first conductive layer 11 into contact with a compound represented by Formula 1A; and
providing the interlayer 15 on one surface of the first conductive layer 11, wherein the first conductive layer 11 comprises gold (Au), and the interlayer 15 includes an inorganic salt:

### Formula 1A

A₄—A₃—(A₁)ₘ₁—(A₂)ₘ₂

### Formula 1

*—A₃—(A₁)ₘ₁—(A₂)ₘ₂

wherein, in Formulae 1A and 1,
A₄ may be a moiety that is displaced upon the bonding of A3 to the surface,
* may indicate a chemical binding site to the surface of the first conductive layer 11, e.g., to a gold atom positioned at the surface,
A₃ may be an atom bonded to the surface of the first conductive layer 11, e.g., A₃ may be bonded to a gold atom at the surface,
A₁ may be a linking group,
A₂ may be a luminescent moiety, and
m1 and m2 may each independently be an integer from 1 to 10, wherein, when m1 is 2 or more, two or more A₁ may be the same or different from each other, and when m2 is 2 or more, two or more A₂ may be to the same or different from each other.

In an embodiment, the method may further include providing the second conductive layer 19 before or after providing the interlayer 15. As a result, the first conductive layer 11 and the second conductive layer 19 may face each other.

In an embodiment, A₄ in Formula 1A may be hydrogen or a substituted or unsubstituted C₁-C₆₀ alkyl group.

In an embodiment, the compound represented by Formula 1A may be a phosphorescent luminescent compound, a fluorescent luminescent compound, or a quantum dot including a hydroxyl group (—OH) or a thiol group (—SH).

In an embodiment, a compound represented by Formula 1A may be, for example, Compound PD80A, PD86A, D1-19A, or FD(17)A:

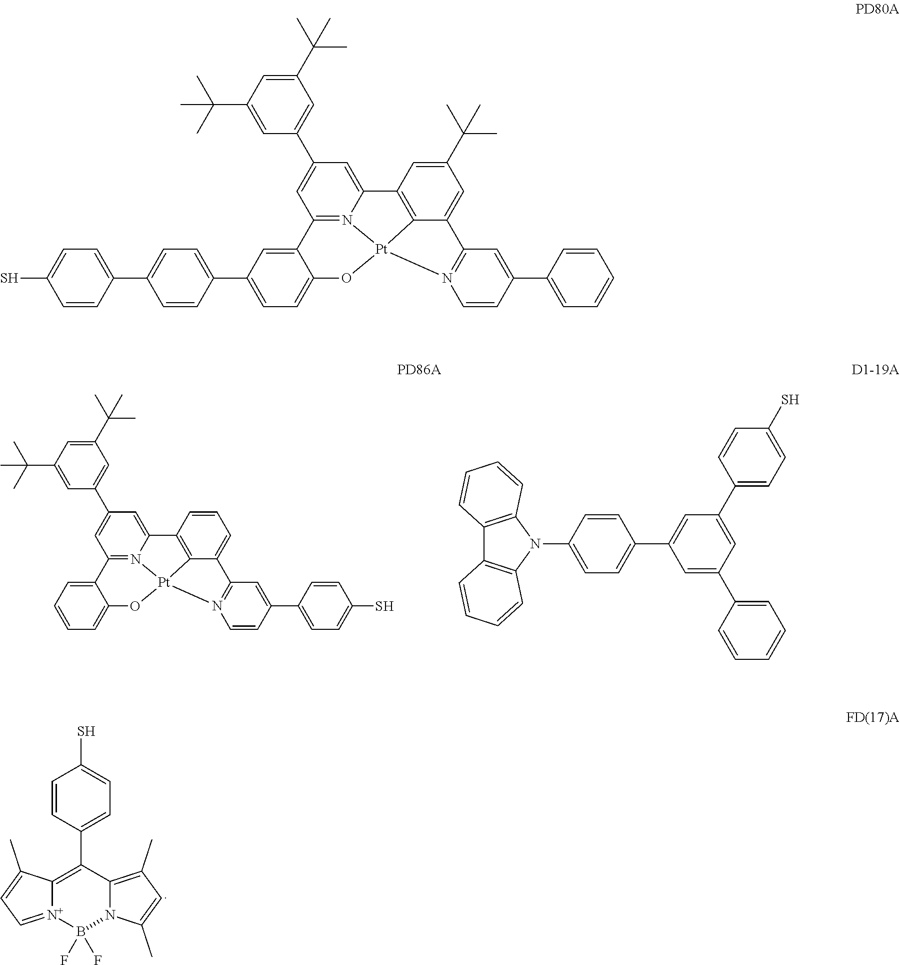

In an embodiment, the process of chemically bonding the light-emitting group 13 represented by Formula 1 to the atom on the surface of the first conductive layer 11 by bringing the first conductive layer 11 into contact with the compound represented by Formula 1A may be performed by a metal (for example, Au)-thiol reaction when, in Formula 1A, A₃ is S and A₄ is hydrogen.

The interlayer 15 of FIG. 1 may be formed between the first conductive layer 11 to which the light-emitting group 13 is chemically bonded and the second conductive layer 19 oriented on the first conductive layer 11 by injecting an inorganic salt thereinto using a syringe.

In an embodiment, the interlayer 15 of the light-emitting device 10 may be formed between the first conductive layer 11 and the second conductive layer 19 by filling an inorganic salt, an insulating material, air, and/or an inert gas using a capillary phenomenon after a spacer is arranged between the first conductive layer 11 and the second conductive layer 19 to secure a gap.

A method of operating the light-emitting device 10 of FIG. 1 may include controlling a voltage applied across the first conductive layer 11 and the second conductive layer 19 of the light-emitting device 10. Accordingly, intensity of light emitted from the light-emitting group 13 of the light-emitting device 10 may be controlled.

For example, the process of controlling the voltage applied across first conductive layer 11 and the second conductive layer 19 of the light-emitting device 10 may include a continuous or step-wise change in the voltage applied across the first conductive layer 11 and the second conductive layer 19 of the light-emitting device 10.

Hereinafter, the light-emitting device will be described in detail through Synthesis Examples and Examples.

### EXAMPLES

### Synthesis Example 1

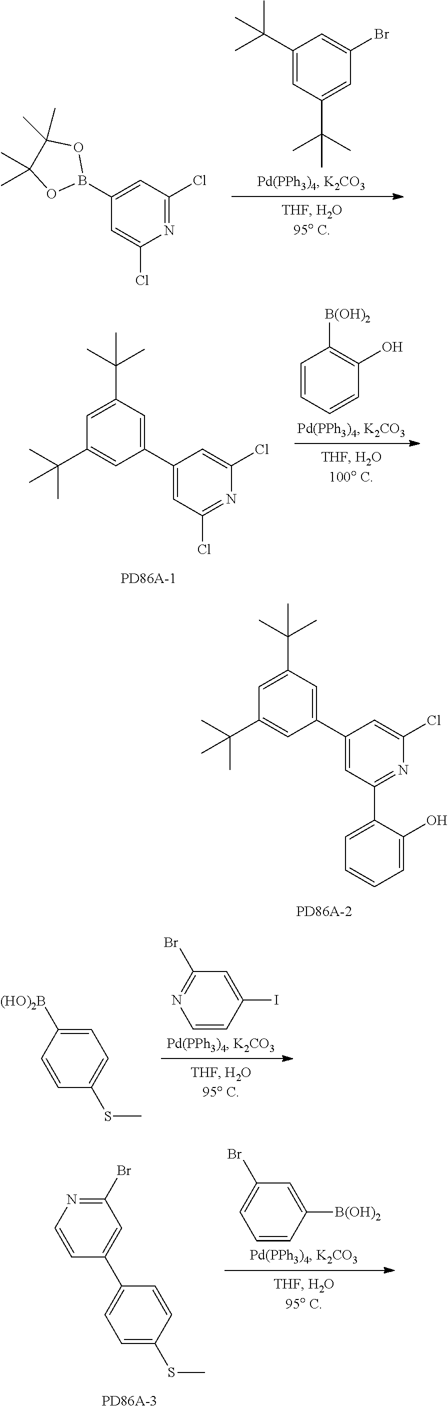

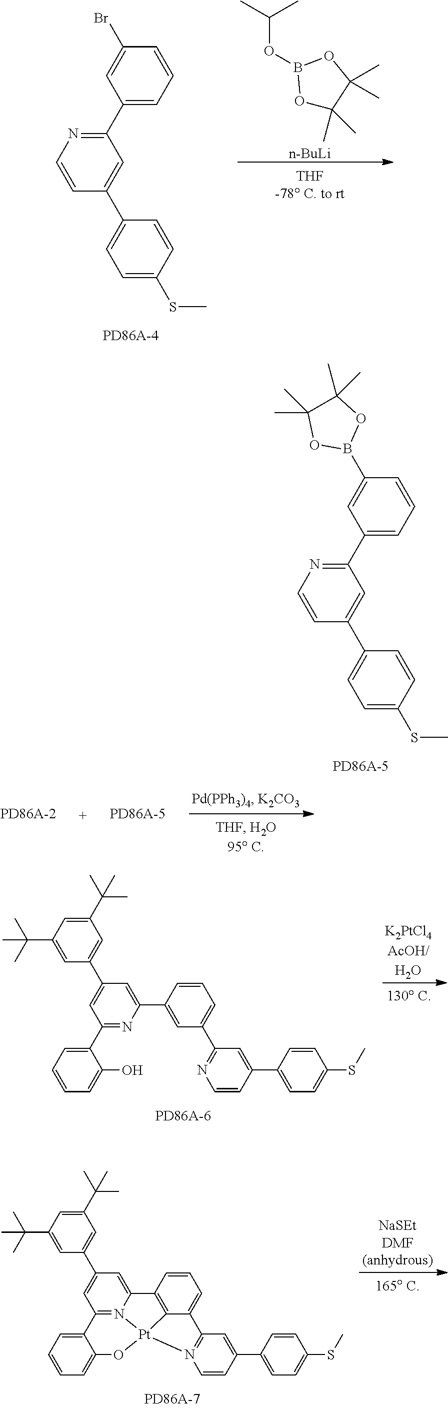

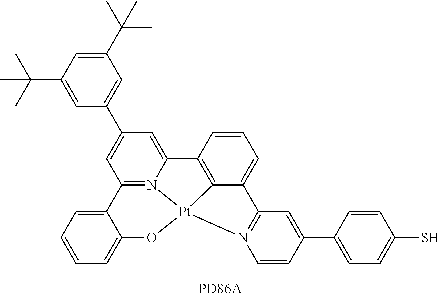

### Synthesis of Intermediate PD86A-1

6.70 g (24.5 mmol) of 2,6-dichloro-4-(4,4,5,5-tetramethyl-1,3,2-dioxaborolan-2-yl)pyridine, 7.90 g (29.4 mmol) of 1-bromo-3,5-di-tert-butylbenzene, 1.41 g (1.22 mmol) of Pd(PPh₃)₄, and 10.1 g (73.4 mmol) of potassium carbonate were added to a mixed solvent including 80 ml of THF and 40 ml of water to prepare a reaction solution, and the reaction solution was stirred under reflux for 24 hours. The reaction solution was cooled to room temperature, and the aqueous layer was removed (separated) by extraction. The organic filtrate was concentrated under vacuum. The product obtained was purified by silica gel column chromatography to obtain 2.40 g (yield of 29%) of Intermediate PD86A-1 as a target compound.
LC-Mass (calculated: 335.12 g/mol, found: M+1=336 g/mol)

### Synthesis of Intermediate PD86A-2

2.30 g (6.84 mmol) of Intermediate PD86A-1, 1.00 g (7.18 mmol) of (2-hydroxyphenyl)boronic acid, 0.553 g (0.479 mmol) of Pd(PPh₃)₄, and 3.78 g (27.4 mmol) of potassium carbonate were added to a mixed solvent including 25 ml of THF and 12 ml of water to prepare a reaction solution. The reaction solution was stirred under reflux for 16 hours. The reaction solution was cooled to room temperature, and the aqueous layer was removed (separated) by extraction. The organic filtrate was concentrated under vacuum. The product obtained was purified by silica gel column chromatography to obtain 2.10 g (yield of 78%) of Intermediate PD86A-2 as a target compound.
LC-Mass (calculated: 393.19 g/mol, found: M+1=394 g/mol)

### Synthesis of Intermediate PD86A-3

5.00 g (29.8 mmol) of 4-(methylthio)phenylboronic acid, 8.45 g (29.8 mmol) of 2-bromo-4-iodopyridine, 3.44 g (2.98 mmol) of Pd(PPh₃)₄, and 12.3 g (89.3 mmol) of potassium carbonate were added to a mixed solvent including 100 ml of THF and 50 ml of water to prepare a reaction solution. The reaction solution was stirred under reflux for 24 hours. The reaction solution was cooled to room temperature, and the aqueous layer was removed (separated) by extraction. The organic filtrate was concentrated under vacuum. The product obtained was purified by silica gel column chromatography to obtain 6.30 g (yield of 76%) of Intermediate PD86A-3 as a target compound.
LC-Mass (calculated: 278.97 g/mol, found: M+1=280 g/mol)

### Synthesis of Intermediate PD86-4

6.00 g (21.4 mmol) of Intermediate PD86A-3, 4.73 g (23.6 mmol) of (3-bromophenyl)boronic acid, 1.24 g (1.07 mmol) of Pd(PPh₃)₄, and 8.88 g (64.2 mmol) of potassium carbonate were added to a mixed solvent including 70 ml of THF and 35 ml of water to prepare a reaction solution. The reaction solution was stirred under reflux for 4 hours. The reaction solution was cooled to room temperature, and the aqueous layer was removed (separated) by extraction. The organic filtrate was concentrated under vacuum. The product obtained was purified by silica gel column chromatography to obtain 5.40 g (yield of 71%) of Intermediate PD86A-4 as a target compound.
LC-Mass (calculated: 355.00 g/mol, found: M+1=356 g/mol)

### Synthesis of Intermediate PD86A-5

1.50 g (4.21 mmol) of Intermediate PD86A-4 was added to 20 ml of THF under nitrogen substitution condition to prepare a reaction solution. After the reaction solution was cooled to −78° C., 3.16 ml (1.6 M sol. in Hx, 5.05 mmol) of n-BuLi was slowly added to the reaction solution, and the reaction solution was stirred for 30 minutes. Afterwards, 1.72 ml (8.42 mmol) of 2-isopropoxy-4,4,5,5-tetramethyl-1,3,2-dioxaborolane was slowly added to the reaction solution. After 30 minutes, the reaction solution was heated to room temperature and stirred for 12 hours. The organic layer was separated by extraction, and the organic layer was concentrated under vacuum. Intermediate PD86A-5 as a target compound was obtained, and Intermediate PD86A-5 was utilized in the next reaction without further purification.

sSynthesis of Intermediate PD86A-6

1.20 g (3.05 mmol) of Intermediate PD86A-2, 1.35 g (3.35 mmol) of Intermediate PD86A-5, 0.246 g (0.213 mmol) of Pd(PPh₃)₄, 1.26 g (9.14 mmol) of potassium carbonate, and 0.157 g (0.914 mmol) of barium hydroxide were added to a mixed solvent including 12 ml of THF and 6 ml of water to prepare a reaction solution. The reaction solution was stirred under reflux for 18 hours. The reaction solution was cooled to room temperature, and the aqueous layer was removed (separated) by extraction. The organic filtrate was concentrated under vacuum. The product obtained was purified by silica gel column chromatography to obtain 1.05 g (yield of 54%) of Intermediate PD86A-6 as a target compound.
LC-Mass (calculated: 634.30 g/mol, found: M+1=635 g/mol)

### Synthesis of Intermediate PD86A-7

0.150 g (0.242 mmol) of Intermediate PD86A-6 and 0.120 g (0.290 mmol) of K₂PtCl₄ were added to a mixed solvent including 3 ml of acetic acid and 0.5 ml of water to prepare a reaction solution. The reaction solution was stirred under reflux for 20 hours. The reaction solution was cooled to room temperature. The reaction solution was filtered to obtain a solid. The solid was washed with water and dried to provide 0.041 g (yield of 21%) of Intermediate PD86A-7 as a target compound.
LC-Mass (calculated: 827.25 g/mol, found: M+1=828 g/mol)

### Synthesis of Compound PD86A

40 mg (0.0484 mmol) of Intermediate PD86A-7 and 40 mg (80%, 0.386 mmol) of sodium ethanethiolate were added to 1 ml of DMF to prepare a reaction solution. The reaction solution was stirred under reflux for 20 hours. The reaction solution was cooled to room temperature. Aq.NH₄Cl solution was added to the reaction solution to form a solid. The solid was then purified by silica gel column chromatography to obtain Compound PD86A (6 mg, yield of 15%).
LC-Mass (calculated: 813.24 g/mol, found: M+1=814 g/mol)

### Synthesis Example 2 (Compound D1-19A)

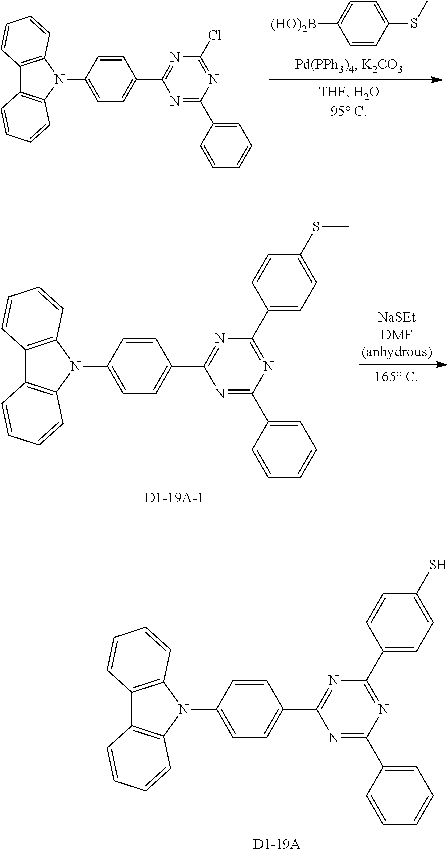 [SMILES: Clc1nc(-c2ccccc2)nc(-c2ccc(-n3c4ccccc4c4ccccc43)cc2)n1 ; CSc1ccc(B(O)O)cc1 ; CSc1ccc(-c2nc(-c3ccccc3)nc(-c3ccc(-n4c5ccccc5c5ccccc54)cc3)n2)cc1 ; Sc1ccc(-c2nc(-c3ccccc3)nc(-c3ccc(-n4c5ccccc5c5ccccc54)cc3)n2)cc1]

### Synthesis of Intermediate D1-19A-1

5.00 g (11.6 mmol) of 9-(4-(4-chloro-6-phenyl-1,3,5-triazin-2-yl)phenyl)-9H-carbazole, 2.14 g (12.7 mmol) of 4-(methylthio)phenylboronic acid, 1.34 g (1.15 mmol) of Pd(PPh₃)₄, and 4.79 g (34.7 mmol) of potassium carbonate were added to a mixed solvent including 40 ml of THF and 20 ml of water to prepare a reaction solution. The reaction solution was stirred under reflux for 12 hours. The reaction solution was cooled to room temperature, and the aqueous layer was removed (separated) by extraction. The organic filtrate was concentrated under vacuum. The product obtained was purified by silica gel column chromatography to obtain 4.73 g (yield of 79%) of Intermediate D1-19A-1 as a target compound.
LC-Mass (calculated: 520.17 g/mol, found: M+1=521 g/mol)

### Synthesis of Compound D1-19A

1.00 g (1.92 mmol) of Intermediate D1-19A-1 and 1.62 g (80%, 15.4 mmol) of sodium ethanethiolate were added to 10 ml of DMF to prepare a reaction solution. The reaction solution was stirred under reflux for 24 hours. The reaction solution was cooled to room temperature, and then placed in an ice bath, and then, 120 ml of 3 N HCl solution was added to the reaction solution to form a solid. The solid was separated through filtration and recrystallization, and Compound D1-19A (0.41 g, yield of 42%) was obtained.
LC-Mass (calculated: 506.16 g/mol, found: M+1=507 g/mol)

### Synthesis Example 3 (Compound FD(17)A)

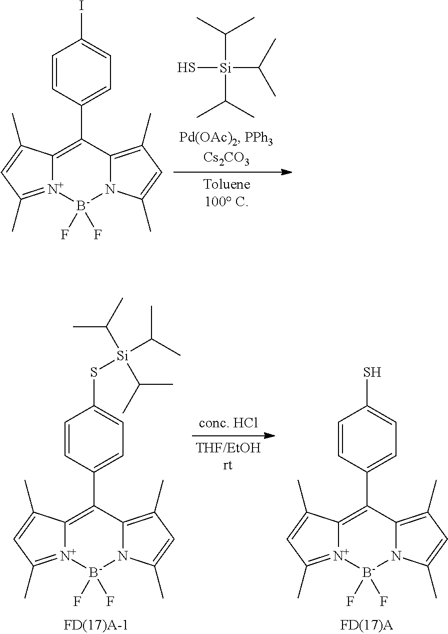

### Synthesis of Intermediate FD(17)A-1

0.420 g (0.933 mmol) of [1-[(3,5-dimethyl-1H-pyrrol-2-yl)(3,5-dimethyl-2H-pyrrol-2-ylidene)methyl]-4-iodobenzene](difluoroborane), 0.249 g (1.31 mmol) of triisopropylsilanethiol, 0.065 g (0.0560 mmol) of Pd(PPh₃)₄, and 0.426 g (1.40 mmol) of cesium carbonate was added to 10 ml of toluene to prepare a reaction solution. The reaction solution was stirred at 100 ° C. for 20 hours. The reaction solution was cooled to room temperature. Aq.NH₄Cl solution was added to the reaction solution to form a solid. The solid was purified by silica gel column chromatography to obtain 0.40 g (yield of 82%) of Intermediate FD(17)A-1 as a target compound.
LC-Mass (calculated: 512.27 g/mol, found: M+1=513 g/mol)

### Synthesis of Compound FD(17)A

0.30 g (0.586 mmol) of Intermediate FD(17)A-1 was added to a mixed solution including 3 ml of THF and 3 ml of EtOH to prepare a reaction solution. 0.20 ml (2.34 mmol) of conc. HCl was added to the reaction solution, and the reaction solution was stirred for 5 hours. The reaction solution was concentrated under vacuum. The product obtained was added to dichloromethane (DCM), re-filtered, and re-concentrated. The product obtained therefrom was then purified by silica gel column chromatography to obtain Compound FD(17)A (0.125 g, yield of 60%).
LC-Mass (calculated: 356.13 g/mol, found: M+1=357 g/mol)

### Example 1

An Au layer (width: 25 mm, length: 11 mm, thickness: 0.7 mm) was immersed in piranha (concentrated H₂SO₄/HNO₃) solution for 1 hour and the surface of the Au layer was then smoothed using a polishing paper. The surface-treated Au layer was immersed in 0.1 M sulfuric acid solution, and cyclic voltammetry was performed for 10 cycles. The foreign substances on the surface of the Au layer were removed. Afterwards, the Au layer was immersed in 0.15 M KCl solution, and the surface of the Au layer was further cleaned using chronoamperometry and cyclic voltammetry.

Next, the Au layer was immersed in a mixture (concentration: 5 mM) including Compound FD(17)A and ethanol. The Au layer was immersed in the mixture for one day and cleaned in order to cause a chemical reaction between Au on the surface of the Au layer and Compound FD(17)A. As a result, Au on the surface of the Au layer and a light-emitting group represented by Formula FD(17)B were chemically bonded to the gold surface.

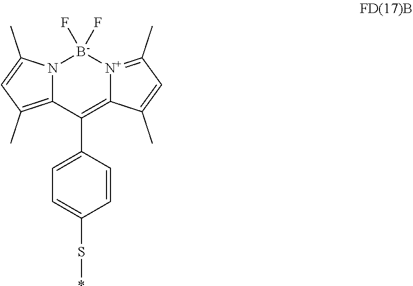 [SMILES: *Sc1ccc(C2=C3C(C)=CC(C)=[N+]3[B-](F)(F)n3c(C)cc(C)c32)cc1]

* in Formula FD(17)B indicates a chemical binding of the thiol sulfur to the surface of the Au layer.

The Au layer to which the light-emitting group represented by Formula FD(17)B was chemically bonded was put into a quartz container. Afterwards, 7.0 ml of 0.1 M NaClO₄ aqueous solution was added to immerse the Au layer. Afterwards, a light-emitting device 1 was manufactured by immersing an MgAg counter electrode in the aqueous solution.

### Evaluation Example 1

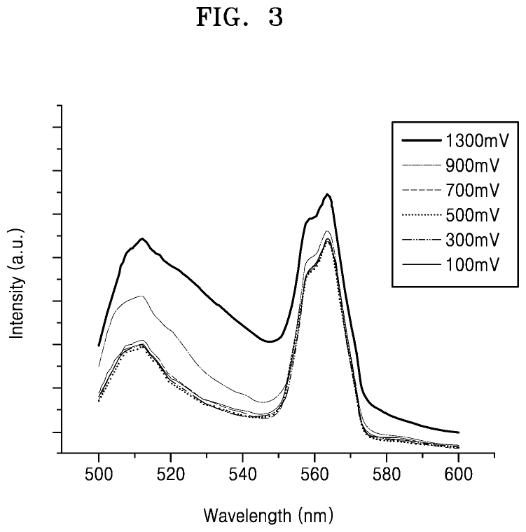

By using an ISC PC1 spectrofluorometer equipped with a Xenon lamp, the photoluminescence (PL) spectrum (at room temperature) of the light-emitting device 1 was measured according to the applied voltage. The voltage applied to the light-emitting device 1 was varied as shown in Table 1. The maximum emission wavelength and relative emission intensity (%) of the light-emitting device 1 is shown to depend on the applied voltage. Results are shown in Table 1 and FIG. 3. When the applied voltage was 100 mV, the relative emission intensity was 100%.

In FIG. 3, a first peak occurring around 512 nm was caused by light emitted from the light-emitting group represented by Formula FD(17)B, and a second peak occurring around 560 nm was caused by light emitted from the Au electrode. The maximum emission wavelength and relative emission intensity (with respect to the intensity at 100 mV) of Table 1 was obtained from data of the first peak occurring around 512 nm.

TABLE 1

| Applied | Maximum emission | Relative emission |
|---|---|---|
| voltage (mV) | wavelength (nm) | intensity (%) |
| +1300 | 512 | 180 |
| +900 | 512 | 135 |
| +700 | 512 | 103 |
| +500 | 512 | 97 |
| +300 | 512 | 98 |
| +100 | 512 | 100 |

From Table 1, one confirmed that with a change in the applied voltage, the light-emitting device 1 emitted light with a significantly increased emission intensity while maintaining the maximum emission wavelength in a certain range.

According to the one or more embodiments, a light-emitting group of a light-emitting device is chemically bonded to a surface, e.g., a gold atom, of a first conductive layer, and intensity of light emitted from the light-emitting group may be controlled by controlling the voltage applied to a first conductive layer and/or a second conductive layer. Moreover, one observes little or no change in the molecular structure of the light-emitting device and/or the light-emitting group as the applied voltage is varied. Therefore, the light-emitting device may be applicable to various light sources, optical sensors, and displays.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the drawings, it will be understood by those of ordinary skill in the art that various changes in form and details may be made therein without departing from the spirit and scope as defined by the following claims.

What is claimed is:

1. A light-emitting device comprising:
a first conductive layer comprising gold;
an interlayer disposed on a surface of the first conductive layer, wherein the interlayer comprises an inorganic salt; and
a plurality of light-emitting groups represented by Formula 1 chemically bonded to the surface of the first conductive layer:
Formula 1
*—A₃—(A₁)ₘ₁—(A₂)ₘ₂
wherein, in Formula 1,
* indicates a chemical binding site of the light emitting groups to gold at the surface of the first conductive layer,
A₃ is bonded to the gold at the surface of the first conductive layer,
A₁ is a linking group,
A₂ is a luminescent moiety, and
m1 and m2 are each independently an integer from 1 to 10, wherein, when m1 is 2 or more, two or more A₁ are the same or different from each other, and when m2 is 2 or more, two or more A₂ are the same or different from each other.

2. The light-emitting device of claim 1, wherein the first conductive layer further comprises silver (Ag), zinc (Zn), aluminum (Al), gallium (Ga), indium (In), thallium (Tl), tin (Sn), carbon, nitrogen, oxygen, or any combination thereof.

3. The light-emitting device of claim 1, wherein the plurality of light-emitting groups is disposed as a monolayer on the surface of the first conductive layer.

4. The light-emitting device of claim 3, wherein a thickness of the first conductive layer or the monolayer is in a range of about 0.1 nanometers to about 5 nanometers.

5. The light-emitting device of claim 3, wherein the monolayer is a self-assembled monolayer.

6. The light-emitting device of claim 1, wherein, in Formula 1, a highest occupied molecular orbital (HOMO) energy level of a conjugate represented by *—A₃—(A₁)ₘ₁—*′ is in a range of about −6.5 eV to about −5.5 eV, wherein *′ indicates a chemical binding site to A₂.

7. The light-emitting device of claim 1, wherein A₃ in Formula 1 is O or S.

8. The light-emitting device of claim 1, wherein A₁ in Formula 1 is a single bond, a substituted or unsubstituted C₁-C₆₀ alkylene group, a substituted or unsubstituted C₂-C₆₀ alkenylene group, a substituted or unsubstituted C₂-C₆₀ alkynylene group, a substituted or unsubstituted C₅-C₃₀ carbocyclic group, or a substituted or unsubstituted C₂-C₃₀ heterocyclic group.

9. The light-emitting device of claim 1, wherein A₂ in Formula 1 is a monovalent group derived from a phosphorescent luminescent compound, a fluorescent luminescent compound, or a quantum dot.

10. The light-emitting device of claim 1, wherein A₂ of Formula 1 is a monovalent group derived from a fluorescent luminescent compound, and the fluorescent luminescent compound is a prompt-fluorescence luminescent compound or a delayed-fluorescence luminescent compound.

11. The light-emitting device of claim 1, wherein the inorganic salt comprises NaClO₄, NaF, Na₂SO₄, KF, KOH, or any combination thereof.

12. The light-emitting device of claim 1, further comprising a second conductive layer disposed on the surface of the first conductive layer with the interlayer disposed between the first and the second conductive layers.

13. The light-emitting device of claim 12, wherein A₂ in Formula 1 is arranged at a distance from the first conductive layer and in a direction toward the second conductive layer.

14. The light-emitting device of claim 12, wherein the second conductive layer comprises lithium (Li), magnesium (Mg), aluminum (Al), Al-Li, calcium (Ca), Mg-In, Mg-Ag, or any combination thereof.

15. The light-emitting device of claim 12, wherein electron density of the light-emitting group changes according to a change in a voltage applied across the first conductive layer and the second conductive layer.

16. The light-emitting device of claim 12, wherein an intensity of light emitted from the light-emitting group changes with the voltage applied across the first conductive layer and the second conductive layer.

17. The light-emitting device of claim 12, wherein a wavelength of light emitted from the light-emitting group changes proportional to a change in the voltage applied across the first conductive layer and the second conductive layer.

18. A method of manufacturing a light-emitting device, the method comprising:
providing a first conductive layer comprising gold;
chemically bonding a light-emitting group represented by Formula 1 to an atom on a surface of the first conductive layer by bringing the first conductive layer into contact with a compound represented by Formula 1A; and
providing an interlayer on the surface of the first conductive layer, wherein the interlayer comprises an inorganic salt:
Formula 1A
A₄—A₃—(A₁)ₘ₁—(A₂)ₘ₂
Formula 1
*—A₃—(A₁)ₘ₁—(A₂)ₘ₂
wherein, in Formulae 1A and 1,
A₄ is a moiety that is displaced upon A3 bonding to the surface,
* indicates a chemical binding site to the surface of the first conductive layer,
A₃ is an atom bonded to the surface of the first conductive layer,
A₁ is a linking group,
A₂ is a luminescent moiety, and
m1 and m2 are each independently an integer from 1 to 10, wherein, when m1 is 2 or more, two or more A₁ are the same or different from each other, and when m2 is 2 or more, two or more A₂ are the same or different from each other.

19. A method of operating a light-emitting device of claim 12, the method comprising controlling a voltage applied across the first and second conductive layers.

20. The method of claim 19, wherein the controlling of the voltage applied across the first and second conductive layers comprises a continuous or step-wise change in the voltage applied.

21. The method of claim 19, wherein the providing of the interlayer includes filling an inorganic salt or an insulating material into a space arranged between the first conductive layer and the second conductive layer.
